(19) United States
(12) Patent Application Publication
(10) Pub. No.: US 2025/0063890 A1
(43) Pub. Date: Feb. 20, 2025

(54) THIN FILM TRANSISTOR SUBSTRATE AND DISPLAY DEVICE USING THE SAME

(71) Applicant: LG Display Co., Ltd., Seoul (KR)

(72) Inventors: Younghyun KO, Paju-si (KR); JuHeyuck BAECK, Paju-si (KR); ChanYong JEONG, Paju-si (KR)

(73) Assignee: LG Display Co., Ltd., Seoul (KR)

(21) Appl. No.: 18/798,111

(22) Filed: Aug. 8, 2024

(30) Foreign Application Priority Data
Aug. 17, 2023 (KR) 10-2023-0107508

(51) Int. Cl. H10K 59/121; H10K 59/126

(52) U.S. Cl. CPC H10K 59/1213; H10K 59/126

(57) ABSTRACT

A thin film transistor substrate includes a substrate; an active layer on the substrate and including an active hole; and a gate electrode on the active layer. The active layer includes a channel part including a first channel part having a first length and a second channel part continuous with the first channel part and having a second length. The active hole includes a first active hole at a boundary portion between the first channel part and the second channel part.

### CROSS-REFERENCE TO RELATED APPLICATIONS

This application claims the benefit of the Korean Patent Application No. 10-2023-0107508 filed on Aug. 17, 2023, which is hereby incorporated by reference as if fully set forth herein.

### BACKGROUND

### Technical Field

The present disclosure relates to a thin film transistor substrate and a display device using the same.

### Discussion of the Related Art

Because thin film transistors can be manufactured on glass or plastic substrates, they are widely used as switching or driving elements of display devices, such as liquid crystal display devices or organic light emitting devices. Based on the material constituting the active layer, thin film transistors can be divided into amorphous silicon thin film transistors in which amorphous silicon is used as an active layer, polycrystalline silicon thin film transistors in which polycrystalline silicon is used as an active layer, and oxide semiconductor thin film transistors in which oxide semiconductor is used as active layers.

Among them, oxide semiconductor thin film transistors (Oxide semiconductor TFTs) have the advantage of being able to easily obtain desired physical properties because they have high mobility and can have a large resistance change depending on the oxygen content. In addition, the manufacturing cost is low because the oxide constituting the active layer may be formed at a relatively low temperature in the manufacturing process of the oxide semiconductor thin film transistor. Due to the nature of the oxide, because the oxide semiconductor is transparent, it is also advantageous to implement a transparent display device.

The thin film transistor may have a high on-current characteristic for image quality, and may have a high S-factor characteristic for excellent gray-scale expression. However, in general, the S-factor and the on-current characteristics are in a trade-off relationship with each other, so as the S-factor increases, the on-current characteristic decreases, and on the contrary, as the on-current characteristic increases, the S-factor decreases.

### SUMMARY

The present disclosure has been made in view of the above problems, and it is a technical benefit of the present disclosure to provide a thin film transistor substrate that is easy to express gray-scale without lowering the on-current characteristics because the active layer has a first channel part and a second channel part that have different lengths and are continuously formed with each other, has an active hole between the first channel part and the second channel part, and has an active hole between the first channel part and the second channel part, and a display device comprising the same.

Accordingly, embodiments of the present disclosure are directed a thin film transistor substrate and a display device using the same that substantially obviate one or more of the problems due to limitations and disadvantages of the related art.

Features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a thin film transistor substrate comprises a substrate; an active layer on the substrate and including an active hole; and a gate electrode on the active layer, wherein the active layer includes a channel part including a first channel part having a first length and a second channel part continuous with the first channel part and having a second length, and wherein the active hole includes a first active hole at a boundary portion between the first channel part and the second channel part.

In another aspect, a thin film transistor substrate comprises a substrate; an active layer on the substrate; and a gate electrode on the active layer, wherein the active layer includes a first channel part overlapping the gate electrode and having a first length, and a second channel part continuous with the first channel part, overlapping the gate electrode, and having a second length, and wherein the active layer includes an active hole so that carrier does not move from the second channel part to the first channel part.

In another aspect, a display device including the thin film transistor substrate comprises a substrate; an active layer on the substrate and including an active hole; and a gate electrode on the active layer, wherein the active layer includes a channel part including a first channel part having a first length and a second channel part continuous with the first channel part and having a second length, and wherein the active hole includes a first active hole at a boundary portion between the first channel part and the second channel part

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1A is a plan view of a thin film transistor substrate according to an embodiment of the present disclosure.

FIG. 1B is a plan view schematically illustrating a state in which a channel of a thin film transistor substrate is formed. In this case, FIG. 1B illustrates a channel of the thin film transistor substrate of FIG. 1A.

FIG. 2A is a cross-sectional view of a thin film transistor substrate according to an embodiment of the present disclosure. In this case, the cross-sectional view of FIG. 2A corresponds to the cross-section taken along the line I-I′ of FIG. 1A.

FIGS. 2B and 2C are cross-sectional views of a thin film transistor substrate according to an embodiment of the present disclosure. In this case, the cross-sectional view of FIG. 2B corresponds to the cross-section taken along the line II-II′ of FIG. 1A, and the cross-sectional view of FIG. 2C corresponds to the cross-section taken along the line III-III′ of FIG. 1A.

FIG. 3A is a schematic view illustrating a current movement path when a thin film transistor substrate according to an embodiment of the present disclosure is driven.

FIG. 3B is a schematic diagram for explaining a condition that electrons does not move the boundary portion between the dualized channel in a thin film transistor substrate according to an embodiment of the present disclosure.

FIGS. 4A, 4B, and 4C are graphs showing a relationship between a gate voltage Vgs and a current Ids of a thin film transistor substrate according to an embodiment of the present disclosure and a thin film transistor substrate according to a comparative example.

FIG. 5 is a graph showing changes in on-current characteristics and S-factor characteristics depending on whether an active hole is applied to a thin film transistor substrate according to an embodiment of the present disclosure and a thin film transistor substrate according to a comparative example.

FIG. 6 is a plan view of a thin film transistor substrate according to another embodiment of the present disclosure.

FIG. 7 is a cross-sectional view of a thin film transistor substrate according to another embodiment of the present disclosure. In this case, the cross-sectional view of FIG. 7 corresponds to the cross-section taken along the line IV-IV′ of FIG. 6.

FIG. 8 is a plan view of a thin film transistor substrate according to another embodiment of the present disclosure.

FIG. 9 is a cross-sectional view of a thin film transistor substrate according to another embodiment of the present disclosure. In this case, the cross-sectional view of FIG. 9 corresponds to the cross-section taken along the line of V-V′ of FIG. 8.

FIG. 10A is a plan view of a thin film transistor substrate according to another embodiment of the present disclosure.

FIG. 10B is a cross-sectional view of a thin film transistor substrate according to another embodiment of the present disclosure. In this case, the cross-sectional view of FIG. 10B corresponds to the cross-section taken along the line VI-VI′ of FIG. 10A.

FIG. 11A is a plan view of a thin film transistor substrate according to another embodiment of the present disclosure.

FIG. 11B is a cross-sectional view of a thin film transistor substrate according to another embodiment of the present disclosure. In this case, the cross-sectional view of FIG. 11B corresponds to the cross-section taken along the line VII-VII′ of FIG. 11A.

FIG. 12 is a plan view of a thin film transistor substrate according to another embodiment of the present disclosure.

FIG. 13 is a cross-sectional view of a thin film transistor substrate according to another embodiment of the present disclosure. In this case, the cross-sectional view of FIG. 13 corresponds to the cross-section taken along the line VIII-VIII′ of FIG. 12.

FIG. 14 is a plan view of a thin film transistor substrate according to another embodiment of the present disclosure.

FIG. 15 is a cross-sectional view of a thin film transistor substrate according to another embodiment of the present disclosure. In this case, the cross-sectional view of FIG. 15 corresponds to the cross-section taken along the line of IX-IX′ of FIG. 14.

FIG. 16A is a plan view of a thin film transistor substrate according to another embodiment of the present disclosure.

FIG. 16B is a schematic plan view illustrating a state in which a channel of a thin film transistor substrate is formed. In this case, FIG. 16B illustrates a channel of the thin film transistor substrate of FIG. 16A.

FIG. 17 is a cross-sectional view of a thin film transistor substrate according to another embodiment of the present disclosure. In this case, the cross-sectional view of FIG. 17 corresponds to the cross-section taken along the line of X-X′ of FIG. 16A.

FIG. 18 is a cross-sectional view of a display device including a thin film transistor substrate according to another embodiment of the present disclosure.

FIG. 19 is a schematic view of a display device according to an embodiment of the present disclosure.

FIG. 20 is a circuit diagram of a pixel included in a display device according to an embodiment of the present disclosure.

FIG. 21 is a circuit diagram of a pixel included in a display device according to another embodiment of the present disclosure.

FIG. 22 is a circuit diagram of a pixel included in a display device according to another embodiment of the present disclosure.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted or may be briefly provided.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

It may understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically. The embodiments of the present disclosure may be carried out independently from each other, or may be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region may be a source electrode, and a drain region may be a drain electrode. Also, a source region may be a drain electrode, and a drain region may be a source electrode.

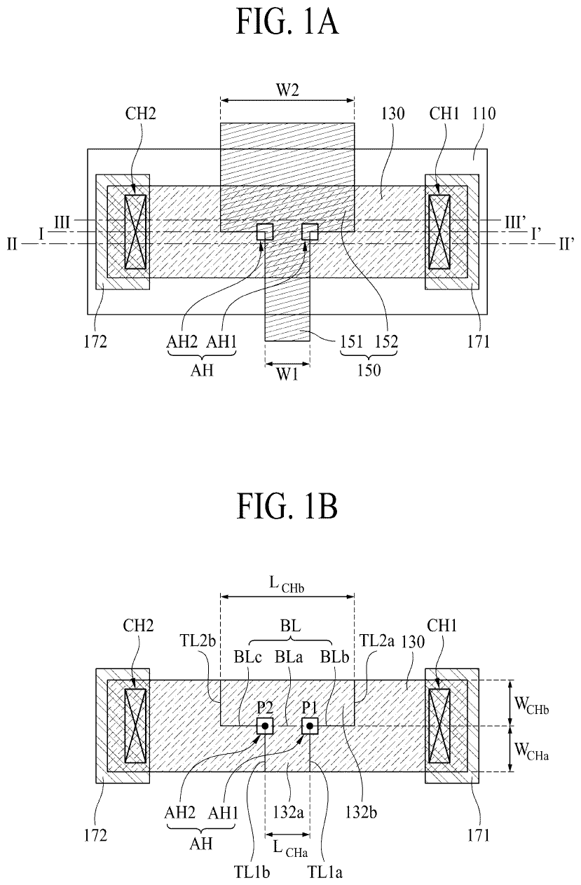

FIG. 1A is a plan view of a thin film transistor substrate according to an embodiment of the present disclosure.

As shown in FIG. 1A, the thin film transistor substrate according to an embodiment of the present disclosure may include a light blocking layer 110, an active layer 130, a gate electrode 150, a source electrode 171, and a drain electrode 172.

The active layer 130 may extend in a first direction, for example, in a horizontal direction. In this case, the first direction may be defined as a direction facing the source electrode 171 and the drain electrode 172.

A first contact hole CH1 may be provided on one side of the active layer 130, for example, a right side of the active layer 130, and a second contact hole CH2 may be provided on another side, for example, a left side of the active layer 130. In this case, one side of the active layer 130 may be electrically connected to the source electrode 171 through the first contact hole CH1, and the other side of the active layer 130 may be electrically connected to the drain electrode 172 through the second contact hole CH2. Meanwhile, although not shown, one side of the active layer 130 may also be electrically connected to the light blocking layer 110 through the extended portion of the source electrode 171.

The gate electrode 150 may include a first portion 151 and a second portion 152 while extending in a second direction, for example, a vertical direction. In this case, the second direction may be defined as a direction orthogonal to the first direction. The first portion 151 may be defined as a partial area of the gate electrode 150 having a first length W1 in a first direction, and the second portion 152 may be defined as another partial area of the gate electrode 150 having a second length W2 in a first direction.

In an embodiment of the present disclosure, the first length W1 of the first portion 151 may be smaller than the second length W2 of the second portion 152. However, the present disclosure is not limited thereto.

The gate electrode 150 may overlap the active layer 130. In this case, each of the first portion 151 and the second portion 152 may overlap the active layer 130, respectively. Because the gate electrode 150 includes the first portion 151 and the second portion 152, and both the first portion 151 and the second portion 152 overlap the active layer 130, the channel part formed in the active layer 130 may be dualized by the first portion 151 and the second portion 152 of the gate electrode 150. Meanwhile, the dualized channel part will be described in detail of FIG. 1B. In this case, the dualized channel part may be defined as a shape in which the same or substantially same thin film transistor has different lengths and continuous channel parts are provided with each other.

According to an embodiment of the present disclosure, the active layer 130 may include an active hole AH, and the active hole AH may include the first active hole AH1 and a second active hole AH2. The first active hole AH1 and the second active hole AH2 may overlap the gate electrode 150. For example, the first active hole AH1 and the second active hole AH2 may overlap a boundary portion between the first portion 151 and the second portion 152 of the gate electrode 150.

The first active hole AH1 may overlap one side of the first portion 151, for example, a right side, while overlapping a boundary portion between the first portion 151 and the second portion 152, and the second active hole AH2 may overlap another side of the first portion 151, for example, a left side, while overlapping a boundary portion between the first portion 151 and the second portion 152.

FIG. 1B is a plan view schematically illustrating a state in which a channel of a thin film transistor substrate is formed. In this case, FIG. 1B illustrates a channel of the thin film transistor substrate of FIG. 1A.

FIG. 1B is a diagram showing other configurations of the thin film transistor substrate of FIG. 1A except for configurations of a light blocking layer and a gate electrode. Accordingly, in FIG. 1B, the active layer 130, a first contact hole CH1 provided at one side of the active layer 130, a second contact hole CH2 provided at another side of the active layer 130, a source electrode 171 connected to one side of the active layer 130 through the first contact hole CH1, and a drain electrode 172 connected to another side of the active layer 130 through the second contact hole CH2 are illustrated.

As shown in FIG. 1B, the active layer 130 may include dualized channel part 132a and 132b dualized by the structure of the gate electrode (see 150 of FIG. 1A). The channel parts 132a and 132b may include a first channel part 132a having a first channel length LCHa in the first direction and a second channel part 132b having a second channel length LCHb in the first direction. In this case, the first channel part 132a and the second channel part 132b are continuously formed.

According to an embodiment of the present disclosure, because the active layer 130 includes the first channel part 132a and the second channel part 132b having different lengths, when the thin film transistor according to an embodiment of the present disclosure is turned on, high on-current characteristics may be secured because current flows through the first channel part 132a having a relatively short length, and high S-factor characteristics may be secured because current flows through the second channel part 132b having a relatively long length. Accordingly, the thin film transistor substrate according to an embodiment of the present disclosure may simultaneously secure high on-current characteristics and high S-factor characteristics.

On the other hand, even if the channel part is dualized, if current flows across channel parts of different lengths when the thin film transistor is turned on, for example, if the charge carrier that moved the second channel part 132b, for example, electrons move across the boundary portion between the first channel part 132a and the second channel part 132b to the first channel part 132a, it is not possible to secure high on-current characteristics and high S-factor characteristics at the same time.

Hereinafter, the principle of preventing or at least reducing carriers, for example electrons, from moving across different channel parts when the thin film transistor substrate according to an embodiment of the present disclosure is turned on will be described.

The first channel part 132a may include a first side T1La adjacent to the source electrode 171 and a second side TL1b adjacent to the drain electrode 172, and the second channel part 132b may include a third side TL2a adjacent to the source electrode 171 and a fourth side TL2b adjacent to the drain electrode 172. Furthermore, a boundary portion BL may be formed between the first channel part 132a and the second channel part 132b. In this case, the boundary portion BL may include a first boundary portion BLa provided at a boundary portion between the first channel part 132a and the second channel part 132b continuous to the first channel part 132a, and a second boundary portion BLb extending in a direction from the first boundary portion BLa to the third side TL2a of the second channel part 132b.

The first boundary portion BLa may be defined as an area formed between a first intersection point P1 where the boundary portion BL and the extension line of the first side TL1a of the first channel part 132a meet, a second intersection point P2 where the boundary portion BL and the extension line of the second side TL1b of the first channel part 132a meet, the second boundary portion BLb may be defined as an area between the first intersection point P1 and the third side TL2a of the second channel part 132b, in an extension line in the direction of the source electrode 171 at the first intersection point P1, and the third boundary portion BLc may be defined as an area between the second intersection point P2 and the fourth side TL2b of the second channel part 132b, in an extension line in the direction of the drain electrode 172 at the second intersection poin P2.

Each of the channel parts 132a and 132b may have a predetermined width in a second direction. For example, the first channel part 132a may have a first width WCHa in the second direction, and the second channel part 132b may have a second width WCHb in the second direction. According to an embodiment of the present disclosure, the first width WCHa of the first channel part 132a may be the same as or substantially the same as the second width WCHb of the second channel part 132b. In all embodiments of the present disclosure, it is assumed that the first width WCHa of the first channel part 132a is the same as the second width WCHb of the second channel part 132b, and although not shown in detail, it is assumed that the first channel part 132a and the second channel part 132b have the same height in a cross-sectional view.

Meanwhile, the first width WCHa and the second width WCHb are not limited to the same or substantially same, but the first width WCHa and the second width WCHb may be different from each other. In this case, the first width WCHa of the first channel part 132a is greater than the second width WCHb of the second channel part 132b. As described above, when the thin film transistor according to an embodiment of the present disclosure is turned on, a high on-current characteristic may be secured because a current flow through the first channel part 132a having a relatively short length and a long width, and a high S-factor characteristic may be secured because a current flows through the second channel part 132b having a relatively long length and a short width. Accordingly, the thin film transistor substrate according to an embodiment of the present disclosure may simultaneously secure a high on-current characteristic and a high S-factor characteristic.

The active hole AH may be provided in the boundary portion BL provided between the first channel part 132a and the second channel part 132b. For example, the first active hole AH1 may be provided between the first boundary portion BLa and the second boundary portion BLb, and may overlap an extension line of the first side TL1a of the first channel part 132a. The second active hole AH2 may be provided between the first boundary portion BLa and the third boundary portion BLc, and may overlap an extension line of the second side TL1b of the first channel part 132a.

The first active hole AH1 and the second active hole AH2 may be formed to be spaced apart from each other at the first boundary portion BLa. For example, the first active hole AH1 and the second active hole AH2 are not continuously formed. By forming in this way, electrons may move only through the first channel part 132a having a relatively short length when the thin film transistor substrate according to an embodiment of the present disclosure is turned on.

According to an embodiment of the present disclosure, because the first active hole AH1 and the second active hole AH2 are formed in the boundary portion BL between the first channel part 132a and the second channel part 132b, when the thin film transistor according to an embodiment of the present disclosure is turned on, electrons may not flow from the first channel part 132a to the second channel part 132b, or electrons may not flow from the second channel part 132b to the first channel part 132a.

According to an embodiment of the present disclosure, electrons may move from the second side TL1b of the first channel part 132a to the first side TL1a of the first channel part 132a, electrons may move from the fourth side TL2b of the second channel part 132b to the third side TL2a of the second channel part 132b, and electrons may not move from the fourth side TL2b of the second channel part 132b to the first side TL1a of the first channel part 132a.

For example, because the active hole AH is provided at the boundary portion BL between the first channel part 132a and the second channel part 132b, the electrons moving from the second channel part 132b to the first channel part 132a may bypass the active hole AH, and thus the moving path of the electrons may be lengthened. In this case, the moving path of the electrons moving from the third side TL2a of the second channel part 132b to the fourth side TL2b of the second channel part 132b may be shorter than the moving path of the electrons moving from the third side TL2a of the second channel part 132b to the second side TL1b of the first channel part 132a, the electrons may not move through the boundary portion BL. Therefore, even if the thin film transistor according to an embodiment of the present disclosure is turned on, the electrons do not cross the first channel part 132a and the second channel part 132b, but move only through each of the first channel part 132a and the second channel part 132b, and as a result, the thin film transistor substrate according to an embodiment of the present disclosure may simultaneously secure high on-current characteristics and high S-factor characteristics.

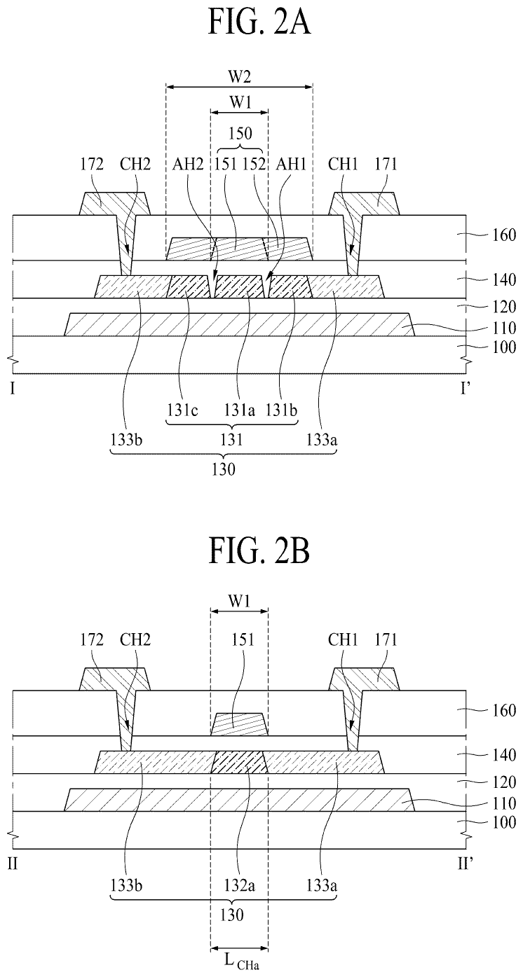

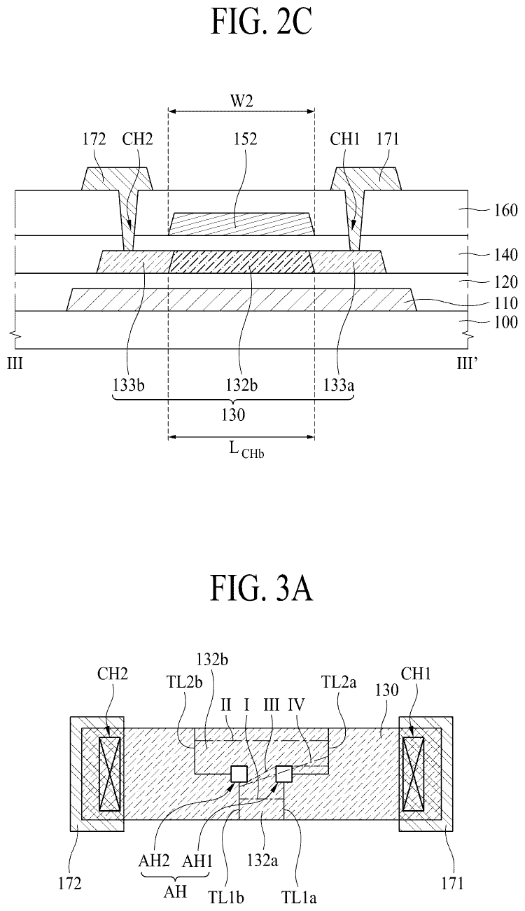

FIG. 2A is a cross-sectional view of a thin film transistor substrate according to an embodiment of the present disclosure. In this case, the cross-sectional view of FIG. 2A corresponds to the cross-section taken along the line I-I′ of FIG. 1A.

As shown in FIG. 2A, a thin film transistor substrate according to an embodiment of the present disclosure may include a substrate 100, a light blocking layer 110, a buffer layer 120, an active layer 130, a gate insulating layer 140, a gate electrode 150, an interlayer insulating layer 160, a source electrode 171, and a drain electrode 172.

The substrate 100 may be made of glass or plastic. In particular, the substrate 100 may be made of transparent plastic having flexible characteristics, for example, polyimide. When the polyimide is used as the substrate 100, considering that a high-temperature deposition process is performed on the substrate 100, heat-resistant polyimide capable of withstanding high temperature may be used.

The light blocking layer 110 may be provided on the substrate 100. The light blocking layer 110 may include a metal or a metal oxide, and may be formed of one metal layer or a metal oxide layer, or may be formed of two or more metal layers or metal oxide layers.

The light blocking layer 110 may be provided under the active layer 130 and overlaps the active layer 130, thereby preventing or at least reducing light introduced from the outside of the thin film transistor substrate from being introduced into the active layer 130. For example, the light blocking layer 110 may reduce or prevent external light from being introduced into the channel part 131 of the active layer 130. Meanwhile, although not illustrated, a separate lower buffer layer may be added between the light blocking layer 110 and the substrate 100 to block air and moisture introduced from the outside of the substrate 100.

The buffer layer 120 may be formed on the substrate 100 and the light blocking layer 110. The buffer layer 120 may protect the active layer 130 by blocking air and moisture. The buffer layer 120 may be made of an inorganic insulating material, such as silicon oxide, silicon nitride, or metal oxide, but is not limited thereto and may be made of an organic insulating material. The buffer layer 120 may be formed of a single layer or a plurality of layers.

The active layer 130 may be provided on the buffer layer 120. The active layer 130 may include a semiconductor material, for example, an oxide semiconductor material. The oxide semiconductor material may include at least one of, for example, an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material.

The active layer 130 may include a channel part 131, a first connection part 133a connected to one side of the channel part 131, for example, a right side, and a second connection part 133b connected to another side of the channel part 131, for example, a left side, and a first active hole AH1 may be provided between the channel part 131 and the first connection part 133a, and a second active hole AH2 may be provided between the channel part 131 and the second connection part 133b.

The channel part 131 may include a first region 131a, a second region 131b provided on one side of the first region 131a, and a third region 131c provided on another side of the first region 131a. In this case, the first region 131a may correspond to the first channel part or the second channel part (see 132a and 132b of FIG. 1B) provided in the first boundary portion (see BLa of FIG. 1B) on the plan view of FIG. 1B, and the second region 131b and the third region 131c may correspond to the second channel part 132b (see BLb and BLc of FIG. 1B) provided in the second boundary portion and the third boundary portion (see BLb and BLc of FIG. 1B), respectively.

The first region 131a may be spaced apart from the second region 131b and the third region 131c by the first active hole AH1 and the second active hole AH2.

The first connection part 133a may be connected to the second region 131b of the channel part 131, and the second connection part 133b may be connected to the third region 131c of the channel part 131.

The first connection part 133a and the second connection part 133b may have conductive characteristics by a conducting process of ion doping or plasma treatment on a semiconductor material using the gate electrode 150 as a mask.

The conducting process may be defined as a process of imparting conductive properties to an oxide semiconductor material. The oxide semiconductor material in which the conducting process has been performed may have conductive properties. The conducting process may include, for example, a doping process using dopant ions and a plasma process of applying plasma to conduct the same. Through the conducting process, a partial region of the active layer 130, for example, the first connection part 133a and the second connection part 133b may be conductive to have conductive properties. Accordingly, the first connection part 133a and the second connection part 133b may have better conductivity than the channel part 131, and each of them may serve as a wiring or source/drain electrode.

The gate insulating layer 140 may be provided on the active layer 130. In detail, the gate insulating layer 140 may be provided on the entire surface of the substrate 100, and may be provided on the active layer 130 and the buffer layer 120. As a result, the active layer 130 may be surrounded by the buffer layer 120 and the gate insulating layer 140.

The gate insulating layer 140 may include a silicon nitride layer (SiNx) or a silicon oxide layer (SiOx), but is not limited thereto. The gate insulating layer 140 may be formed of a single layer or a plurality of layers including an inorganic insulating material and/or an organic insulating material. Meanwhile, although not illustrated, the gate insulating layer 140 is not limited to being provided on the entire surface of the substrate 100, and may be provided to coincide with one end and the other end of the gate electrode 150.

The gate electrode 150 may be provided on the gate insulating layer 140. The gate electrode 150 may be provided on the active layer 130. For example, the gate electrode 150 may overlap the channel part 131 of the active layer 130. The gate electrode 150 may include a first portion 151 having a first length W1 in the first direction and a second portion 152 having a second length W2 in the first direction.

The first portion 151 may overlap the first region 131a of the channel part 131, but may not overlap the second region 131b and the third region 131c of the channel part 131. Meanwhile, the second portion 152 may not overlap the first region 131a of the channel part 131, but may overlap the second region 131b and the third region 131c of the channel part 131. The first portion 151 and the second portion 152 may overlap the first active hole AH1 and the second active hole AH2, respectively.

The gate electrode 150 may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). The gate electrode 150 may have a structure including one metal layer or a multilayer structure including at least two metal layers each having different physical properties.

The interlayer insulating layer 160 may insulate between the gate electrode 150 and the source electrode 171 and further insulate between the gate electrode 150 and the drain electrode 172. The interlayer insulating layer 160 may be formed of a single layer or a plurality of layers including an inorganic insulating material and/or an organic insulating material.

A first contact hole CH1 and a second contact hole CH2 may be provided in the interlayer insulating layer 160. Accordingly, a portion of the upper surface of the first connection part 133a of the active layer 130 may be exposed by the first contact hole CH1, and further, a portion of the upper surface of the second connection part 133b of the active layer 130 may be exposed by the second contact hole CH2.

The source electrode 171 and the drain electrode 172 may be disposed on the interlayer insulating layer 160. The source electrode 171 and the drain electrode 172 may be formed of the same or substantially same material as the gate electrode 150, but are not limited thereto and may be formed of a material according to knowledge of the art. Furthermore, although not shown, the source electrode 170 may also be electrically connected to the light blocking layer 110.

FIGS. 2B and 2C are cross-sectional views of a thin film transistor substrate according to an embodiment of the present disclosure. In this case, the cross-sectional view of FIG. 2B corresponds to the cross-section taken along the line II-II′ of FIG. 1A, and the cross-sectional view of FIG. 2C corresponds to the cross-section taken along the line III-III′ of FIG. 1A. Meanwhile, because the thin film transistor substrate of FIG. 2B and FIG. 2C is the same as or substantially the same as the thin film transistor substrate of FIG. 2A except for the configuration of the active layer 130, different configurations will be mainly described below.

As shown in FIG. 2B and FIG. 2C, the active layer 130 may include a first channel part 132a (or a second channel part 132b), a first connection part 133a provided on one side of the first channel part 132a (or a second channel part 132b), for example, on another side of the first channel part 132a (or a second channel part 132b), and a second connection part 133b provided on the left side.

First, as shown in FIG. 2B, the first channel part 132a may have a first channel length LCHa in the first direction. A first portion 151 of the gate electrode (see 150 of FIG. 2A) may be provided on the first channel part 132a, and one end and another end of the first channel part 132a may correspond to one end and another end of the first portion 151, respectively.

According to an embodiment of the present disclosure, the active layer 130 may perform a conducting process using the first portion 151 as a mask, so that the first channel part 132a may be determined by the first portion 151 of the gate electrode (see 150 of FIG. 2A). Accordingly, one end and another end of the first channel part 132a may correspond to one end and another end of the first portion 151 of the gate electrode (see 150 of FIG. 2A), respectively.

The first channel length LCHa of the first channel part 132a in the first direction may be the same as or substantially the same as the first length W1 of the first portion 151 in the first direction. However, in applying the actual process, the first channel length LCHa of the channel part 132a may be relatively shortened by dopant ions or plasma diffused from the first connection part 133a and the second connection part 133b, and in this case, the first length W1 of the first portion 151 may be greater than the first channel length LCHa. Likewise, as shown in FIG. 2C, the second channel part 132b may have a second channel length LCHb in the first direction. A second portion 152 of the gate electrode (see 150 of FIG. 2A) may be provided on the second channel part 131b, and one end and another end of the second channel part 132b may correspond to one end and another end of the second portion 152, respectively.

According to an embodiment of the present disclosure, the active layer 130 performs a conducting process using the second portion 152 as a mask, so that the second channel part 132b may be determined by the second portion 152 of the gate electrode (see 150 of FIG. 2A). Accordingly, one end and another end of the second channel part 132b may correspond to one end and another end of the second portion 152 of the gate electrode (see 150 of FIG. 2A), respectively.

The second channel length LCHb of the second channel part 132b in the first direction may be the same as or substantially the same as the second length W2 of the second portion 152 in the first direction. However, in applying the actual process, the second channel length LCHb of the second channel part 132b may be relatively shortened by dopant ions or plasma diffused from the first connection part 133a and the second connection part 133b, and in this case, the second length W2 of the second portion 152 may be greater than the second channel length LCHb of the second channel part 132b.

With reference to FIGS. 2B and 2C, as the gate electrode (see 150 of FIG. 2A) includes the first portion 151 and the second portion 152, the channel parts 132a and 132b provided in the active layer 130 may also include the first channel part 132a and the second channel part 132b having different lengths. As a result, because the channel parts 132a and 132b according to an embodiment of the present disclosure are divided into the first channel part 132a and the second channel part 132b, a thin film transistor substrate having improved on-current characteristics and improved S-factor characteristics may be implemented.

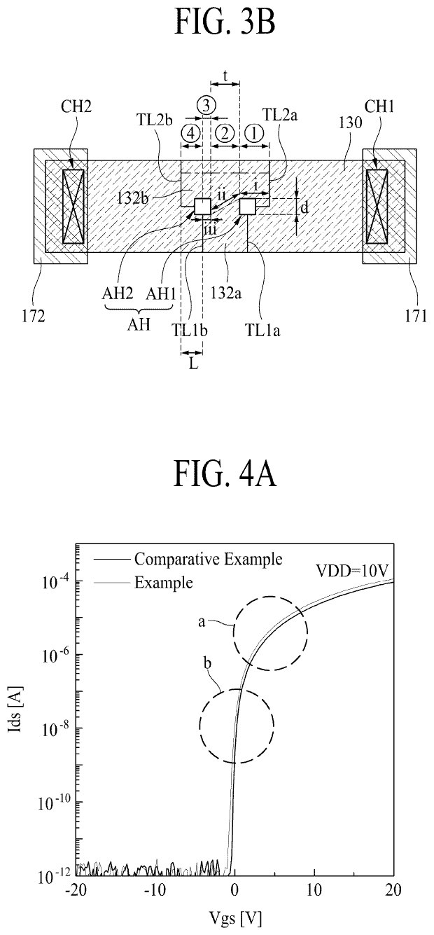

FIG. 3A is a schematic view illustrating a current movement path when a thin film transistor substrate according to an embodiment of the present disclosure is driven, and FIG. 3B is a schematic diagram for explaining a condition that electrons do not move the boundary portion between the dualized channel in a thin film transistor substrate according to an embodiment of the present disclosure.

FIGS. 3A and 3B schematically show only the active layer 130, the source electrode 171, and the drain electrode 172 except for the configuration of the gate electrode and the light blocking layer in the thin film transistor substrate according to an embodiment of the present disclosure.

As shown in FIG. 3A, because the channel parts 132a and 132b are dualized in the thin film transistor substrate according to an embodiment of the present disclosure, when the thin film transistor is turned on, electrons move along the first path I and the second path II. The first path I is a path through which electrons move through the first channel part 132a, and electrons may move from the source electrode 171 to the drain electrode 172 via the first side TL1a of the first channel part 132a and the second side TL1b of the first channel part 132a. The second path II is a path through which electrons move through the second channel part 132b, and electrons may move from the source electrode 171 to the drain electrode 172 via the third side TL2a of the second channel part 132b and the fourth side TL2b of the second channel part 132b.

According to an embodiment of the present disclosure, because the active hole AH is provided at the boundary portion (see BL of FIG. 1B) between the first channel part 132a and the second channel part 132b, electrons may not move along the third path III and the fourth path IV even when the thin film transistor is turned on. For example, the third path III is the shortest distance among the paths crossing the first channel part 132a from the second channel part 132b, and electrons may move from the source electrode 171 to the drain electrode 172 in order through the third side TL2a of the second channel part 132b, an one side, for example, an upper side of the first active hole AH1, the boundary portion (see BLa of FIG. 1B) disposed between the first channel part 132a and the second channel part 132b, an one side, for example, a bottom side of the second active hole AH2, and the second side TL1b of the first channel part 132a.

According to an embodiment of the present disclosure, because the moving distance of electrons passing through the third path III is longer than the moving distance of electrons passing through the first path I and/or the second path II, when the thin film transistor according to an embodiment of the present disclosure is turned on, electrons only move along the first path I and/or the second path II, and do not move across the first channel part 132a and the second channel part 132b.

Meanwhile, a condition in which the length of the third path III is formed to be longer than the length of the first path I and the second path II will be described in detail with reference to FIG. 3B.

Meanwhile, the fourth path IV may correspond to a straight path extending from the third side TL2a of the second channel part 132b to the second side TL1b of the first channel part 132a. In this case, because the first active hole AH1 is provided to overlap the straight line extending from the third side TL2a of the second channel part 132b to the second side TL1b of the first channel part 132a, electrons may not move through the fourth path IV.

As a result, according to an embodiment of present disclosure, because electrons do not move across the first channel part 132a and the second channel part 132b even if the thin film transistor is turned on, a thin film transistor substrate with improved on-current and S-factor characteristics can be implemented simultaneously.

Next, a condition for forming the length of the first path I and the second path II of the thin film transistor according to an embodiment of the present disclosure to be shorter than the length of the third path III will be described in detail with reference to FIG. 3B. Meanwhile, because the length of the first path I is shorter than the length of the second path II, the length of the second path II is compared with the length of the third path III to describe a condition in which electrons do not move the boundary portion (see BL of FIG. 1B) disposed between the first channel part 132a and the second channel part 132b.

As shown in FIG. 3B, the second path (see II of FIG. 3A) includes area [symbol] , area [symbol] , area [symbol] , and area [symbol] , and the third path (see III of FIG. 3A) includes area i, area ii, and are iii.

In this case, lengths of areas [symbol] and [symbol] of the second path (see II of FIG. 3A) are the same as or substantially the same as lengths of areas i and iii of the third path (see III of FIG. 3A), respectively. Therefore, in order for the length of the second path to be shorter than the length of the third path, the following Equation 1 is satisfied.

$$a length of area + a length of area < a length of area ii \qquad [ Equation 1 ]$$

In this case, the length of area [symbol] may be defined as the distance t, which is the distance between the first active hole AH1 and the second active hole AH2, the length of area [symbol] may be defined as L, which is the distance between the second side TL1b of the first channel part 132a and the extension line of the fourth side TL2b of the second channel part 132b, and the length of area ii may satisfy the following Equation 2.

$$a length of area ii = {( {d}^{2} + {t}^{2} )}^{1 / 2} \qquad [ Equation 2 ]$$

As a result, Equation 1 may be summarized as the following Equation 3.

$$t + L < {( {d}^{2} + {t}^{2} )}^{1 / 2} , \qquad [ Equation 3 ]$$

By summarizing this with respect to the distance t between the active holes AH, Equation 4 may be obtained as follows. Meanwhile, because the first active hole AH1 and the second active hole AH2 are not continuous with each other, the distance t between the active holes AH is greater than 0.

$$0 < t < ( {d}^{2} - {L}^{2} ) / ( 2 L ) \qquad [ Equation 4 ]$$

As a result, when the distance t between the first active hole AH1 and the second active hole AH2 satisfies Equation 4, the length of the second path (see II of FIG. 3A) is shorter than the length of the third path (see III of FIG. 3A), and thus electrons move from the first side TL1a of the first channel part 132a to the second side TL1b of the first channel part 132a, and move from the third side TL2a of the second channel part 132b to the fourth side TL2b of the second channel part 132b, but electrons may not move from the third side TL2a of the second channel part 132b to the second side TL1b of the first channel part 132a.

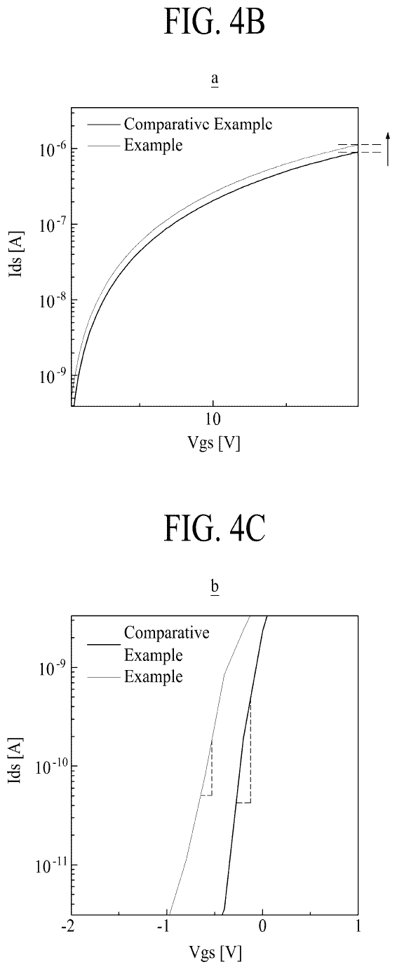

FIGS. 4A, 4B, and 4C are graphs showing a relationship between a gate voltage Vgs and a current Ids of a thin film transistor substrate according to an embodiment of the present disclosure and a thin film transistor substrate according to a comparative example.

FIG. 4A illustrates a relationship between a gate voltage Vgs applied to a thin film transistor and a current Ids flowing through a channel when a voltage VDD of a driving power source is 10 V, FIG. 4B is an enlarged graph of an area a of FIG. 4A, and FIG. 4C is an enlarged graph of an area b of FIG. 4A. In this case, in FIGS. 4A to 4C, a thick solid line is a graph of a comparative example, and a thin solid line is a graph of an embodiment.

As shown in FIG. 4B, when the thin film transistor substrate according to an embodiment of the present disclosure is turned on, the on-current Ids characteristic is increased (arrow direction) compared to that of the thin film transistor substrate according to the comparative example.

Furthermore, as shown in FIG. 4C, it may be seen that when the thin film transistor substrate according to the embodiment of the present disclosure is turned on, the slope of the current Ids graph with respect to the gate voltage Vgs is greater in the case of the comparative example than in the case of the embodiment.

Because the S-factor is inversely proportional to the slope of the current Ids graph with respect to the gate voltage Vgs, it may be seen from the above fact that the S-factor characteristics of the thin film transistor according to an embodiment of the present disclosure are improved compared to the thin film transistor according to the comparative example. As a result, when looking at FIGS. 4A, 4B, and 4C together, the thin film transistor substrate according to an embodiment of the present disclosure may secure improved on-current characteristics while at the same time securing improved S-factor characteristics.

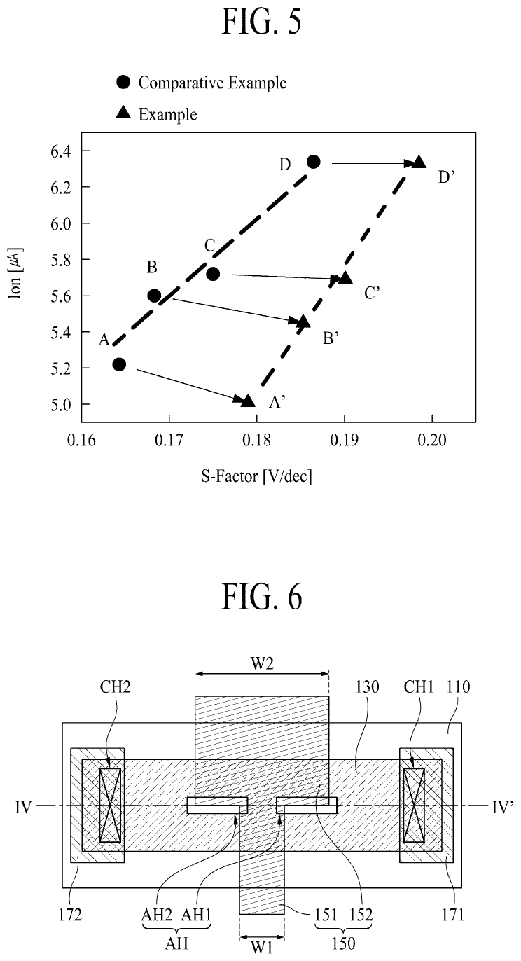

FIG. 5 is a graph showing changes in on-current characteristics and S-factor characteristics depending on whether an active hole is applied to the thin film transistor substrate according to the embodiment of the present disclosure, and the thin film transistor substrate according to comparative examples, and Table 1 below is a table showing Comparative Examples 1 to 4 A, B, C, and D to which the active hole (see AH of FIG. 1A) is not applied. In this case, Comparative Examples 1 to 4 A, B, C, and D are arranged so that the ratio W2/W1 of the second length W2 of the second portion (see 152 of FIG. 1A) to the first length W1 of the first portion (see 151 of FIG. 1A) of the gate electrode (see 150 of FIG. 1A) is sequentially increased.

Table 2 below shows comparative example 5 A′ in which an active hole (see AH of FIG. 1a) is applied, but the channel part (see 132a and 132b) is not dualized, and examples 1 to 3 B′, C′, and D′ in which an active hole (see AH of FIG. 1A) is applied in this case, comparative example 5 A′ and examples 1 to 3 (see AH of FIG. 1A) to which the active hole (see AH of FIG. 1A) is applied are arranged so that the ratio W2/W1 of the second length W2 to the first length W1 is sequentially increased.

In FIG. 5, the portion indicated as circles relates to the case in which the active hole (see AH of FIG. 1A) is not applied as Comparative Examples 1 to 4 A to D, and the portion indicated as triangles relates to the case in which the active hole (see AH of FIG. 1A) is applied as Comparative Examples 5 A′ and Examples 1 to 3 B‘ to D’.

TABLE 1

| | Comparative | Comparative | Comparative | Comparative |
|---|---|---|---|---|
| | Example | Example | Example | Example |
| | 1(A) | 2(B) | 3(C) | 4(D) |
| W1 | 5.5 μm | 7 μm | 7.5 μm | 8 μm |
| W2 | 5.5 μm | 4 μm | 3.5 μm | 3 μm |
| W2/W1 | 1 | 1.75 | 2.14 | 2.67 |

TABLE 2

| | Comparative | Example | Example | Example |
|---|---|---|---|---|
| | Example 5(A′) | 1(B′) | 2(C′) | 3(D′) |
| W1 | 5.5 μm | 7 μm | 7.5 μm | 8 μm |
| W2 | 5.5 μm | 4 μm | 3.5 μm | 3 μm |
| W2/W1 | 1 | 1.75 | 2.14 | 2.67 |

According to FIGS. 5, Table 1 and Table 2, both cases in which the active hole (see AH of FIG. 1A) is not applied and in which the active hole (see AH of FIG. 1A) is applied, as the second length (see W2 of FIG. 1A) of the second portion (see 152 of FIG. 1A) with respect to the first length (see W1 of FIG. 1A) of the first portion (see 151 of FIG. 1A) is increased, the S-factor characteristic and the on-current characteristic are increased. Furthermore, as shown the case in which the active hole (see AH of FIG. 1A) is applied and the case in which the active hole (see AH of FIG. 1A) is not applied, it may be confirmed that when the active hole (see AH of FIG. 1A) is applied, improved S-factor characteristics can be ensured compared to similar on-current characteristics as compared to when the active hole (see AH of FIG. 1A) is not applied.

As a result, the thin film transistor substrate according to an embodiment of the present disclosure can secure improved on-current Ion and S-Factor characteristics when the second length (see W2 of FIG. 1A) of the second portion (see 152 of FIG. 1A) with respect to the first length (see W1 of the FIG. 1A) of the first portion (see 151 of FIG. 1A) of the gate electrode (see 150 of FIG. 1A) is increased, and it may be seen that when the active hole (see AH of FIG. 1A) is applied, improved S-factor characteristics may be ensured as compared to when the active hole (see AH of FIG. 1A) is not applied.

FIG. 6 is a plan view of a thin film transistor substrate according to another embodiment of the present disclosure. Meanwhile, because the thin film transistor substrate according to FIG. 6 is the same as or substantially the same as the thin film transistor substrate according to FIG. 1A except for the configuration of the active hole, different configurations will be mainly described below.

As shown in FIG. 6, according to another embodiment of the present disclosure, unlike the thin film transistor substrate according to FIG. 1A, the active hole AH may further extend in a first direction, for example, a horizontal direction.

The first active hole AH1 of the active hole AH may extend from the center of the gate electrode 150 toward the source electrode 171, and the second active hole AH2 of the active hole AH may extend from the center of the gate electrode 150 toward the drain electrode 172.

The first active hole AH1 may extend in the horizontal direction to overlap one end, for example, a right end, of the second portion 152 of the gate electrode 150, and the second active hole AH2 may extend in the horizontal direction to overlap the other end, for example, a left end, of the second portion 152 of the gate electrode 150.

By forming in this way, the first active hole AH1 may overlap the extension line of the third side (see TL2a of FIG. 1B) of the second channel part (see 132b in FIG. 1B), and the second active hole AH2 may overlap the extension line of the fourth side (see TL2b in FIG. 1B) of the second channel part (see 132b in FIG. 1B).

Meanwhile, although not illustrated in the drawing, the first active hole AH1 may extend in the horizontal direction to coincide with the one end of the second portion 152, or may not extend to the one end of the second portion 152. Likewise, the second active hole AH2 may extend in the horizontal direction to coincide with another end of the second portion 152, or may not extend to another end of the second portion 152.

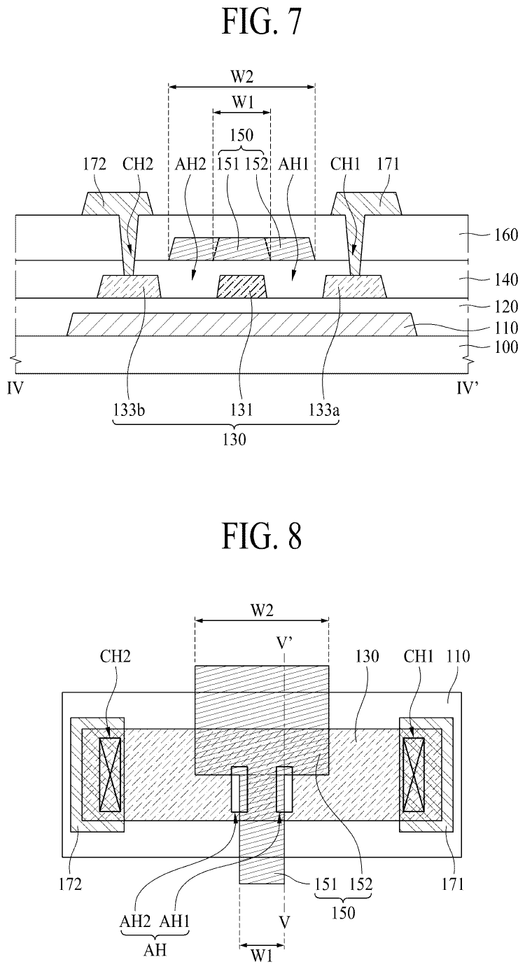

FIG. 7 is a cross-sectional view of a thin film transistor substrate according to another embodiment of the present disclosure. In this case, the cross-sectional view of FIG. 7 corresponds to the cross-section taken along the line IV-IV′ of FIG. 6. Meanwhile, because the thin film transistor substrate of FIG. 7 is the same as or substantially the same as the thin film transistor substrate of FIG. 2A except for the configuration of the active hole, different configurations will be mainly described below.

As shown in FIG. 7, a thin film transistor substrate according to another embodiment of the present disclosure may include a substrate 100, a light blocking layer 110, a buffer layer 120, an active layer 130, a gate insulating layer 140, a gate electrode 150, an interlayer insulating layer 160, a source electrode 171, and a drain electrode 172.

The active layer 130 may include a channel part 131, a first connection part 133a provided on one side of the channel part 131, for example, on the right side, and a second connection part 133b provided on another side of the channel part 131, for example, on the left side, and an active hole AH including a first active hole AH1 and a second active hole AH2 may be provided in the active layer 130.

The first active hole AH1 may be provided between the channel part 131 and the first connection part 133a, and the second active hole AH2 may be provided between the channel part 131 and the second connection part 133b.

The first active hole AH1 and the second active hole AH2 may overlap the first portion 151 and the second portion 152 of the gate electrode 150, respectively.

According to an embodiment of the present disclosure, the first active hole AH1 may extend from the channel part 131 toward the first connection part 133a, and in this case, a portion of the first active hole AH1 may not overlap the gate electrode 150. Likewise, the second active hole AH2 may extend from the channel part 131 toward the second connection part 133b, and in this case, a portion of the second active hole AH2 may not overlap the gate electrode 150.

FIG. 8 is a plan view of a thin film transistor substrate according to another embodiment of the present disclosure. Meanwhile, because the thin film transistor substrate according to FIG. 8 is the same as or substantially the same as the thin film transistor substrate according to FIG. 1A except for the configuration of the active hole, different configurations will be mainly described below.

As shown in FIG. 8, unlike the thin film transistor substrate according to FIG. 1A, the active hole AH may further extend in a second direction, for example, in a vertical direction. For example, the active hole AH may include a first active hole AH1 and a second active hole AH2, and the first active hole AH1 and the second active hole AH2 may extend in a direction in which the first portion 151 extends from a boundary portion of the gate electrode 150. The first active hole AH1 and the second active hole AH2 may extend in the vertical direction, but the first active hole AH1 and the second active hole AH2 may not extend past the lower side of the active layer 130.

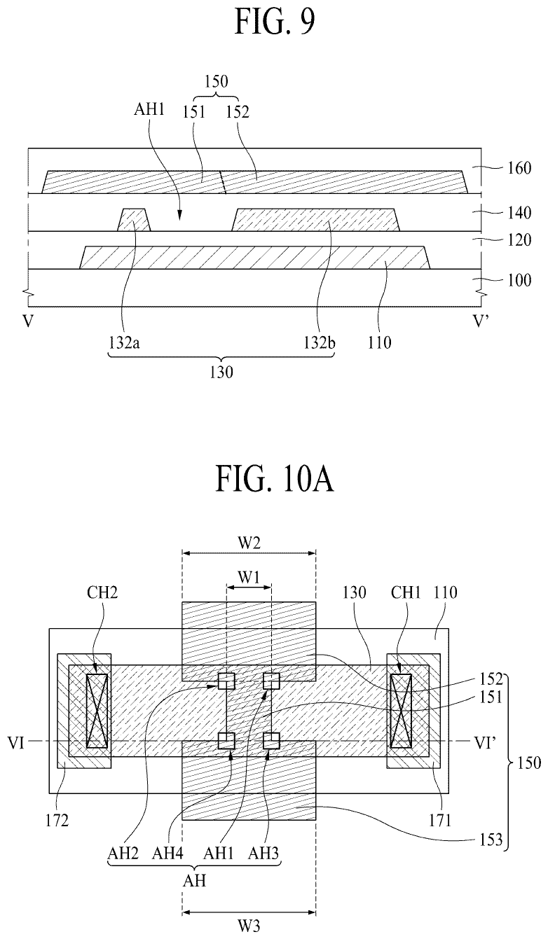

FIG. 9 is a cross-sectional view of a thin film transistor substrate according to another embodiment of the present disclosure. In this case, the cross-sectional view of FIG. 9 corresponds to the cross-section taken along the line of V-V′ of FIG. 8. Meanwhile, the thin film transistor substrate of FIG. 9 is the same as or substantially the same as the thin film transistor substrate of FIG. 2A except for the configuration of the active hole, and thus different configurations will be mainly described below.

As shown in FIG. 9, a thin film transistor substrate according to another embodiment of the present disclosure may include a substrate 100, a light blocking layer 110, a buffer layer 120, an active layer 130, a gate insulating layer 140, a gate electrode 150, an interlayer insulating layer 160, a source electrode 171, and a drain electrode 172.

The active layer 130 may include a first channel part 132a and a second channel part 132b, and a first active hole AH1 may be provided between the first channel part 132a and the second channel part 132b. The gate electrode 150 may be provided on the active layer 130, and the first portion 151 of the gate electrode 150 may overlap the first channel part 132a and the first active hole AH1. The second portion 152 of the gate electrode 150 may overlap the second channel part 132b and the first active hole AH1.

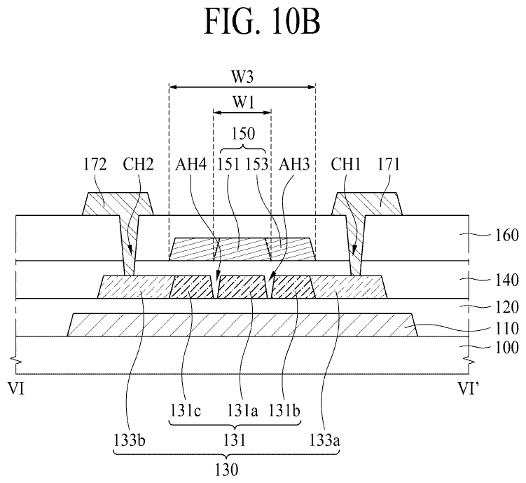

FIG. 10A is a plan view of a thin film transistor substrate according to another embodiment of the present disclosure. Meanwhile, because the thin film transistor substrate according to FIG. 10A is the same as or substantially the same as the thin film transistor substrate according to FIG. 1A except for configurations of the active hole and the gate electrode, different configurations will be mainly described below.

As shown in FIG. 10A, the gate electrode 150 may include a first portion 151, a second portion 152, and a third portion 153. the first portion 151 may have a first length W1 in a first direction, for example, in a horizontal direction, the second portion 152 may have a second length W2 in the first direction, and the third portion 153 may have a third length W3 in the first direction. In this case, the first length W1 of the first portion 151 may be shorter than the second length W2 of the second portion 152 and the third length W3 of the third portion 153.

According to an embodiment of the present disclosure, the second portion 152 and the third portion 153 may be symmetrically provided with respect to the first portion 151. Accordingly, the second length W2 of the second portion 152 may be the same as or substantially the same as the third length W3 of the third portion 153. However, the present disclosure is not limited thereto, and the second length W2 and the third length W3 may be different from each other.

According to an embodiment of the present disclosure, the second portion 152, the first portion 151, and the third portion 153 may be provided in order from top to bottom of the drawing. Accordingly, the first portion 151 may be continuous with the second portion 152 and the third portion 153, respectively, and the second portion 152 and the third portion 153 may be spaced apart from each other with the first portion 151 interposed therebetween.

Accordingly, a boundary portion may be provided between the first portion 151 and the second portion 152 continuous with the first portion 151, and a boundary portion may be provided between the first portion 151 and the third portion continuous with the first portion 151.

The active hole AH may include a first active hole AH1 and a third active hole AH3 adjacent to the source electrode 171, and a second active hole AH2 and a fourth active hole AH4 adjacent to the drain electrode 172.

The first active hole AH1 and the second active hole AH2 may overlap the first portion 151 and the second portion 152 of the gate electrode 150. For example, the first active hole AH1 and the second active hole AH2 may overlap a boundary portion between the first portion 151 and the second portion 152, and further, the first active hole AH1 may overlap one side of the first portion 151, for example, a right side, while overlapping a boundary portion between the first portion 151 and the second portion 152. and the second active hole AH2 may overlap another side of the first portion 151, for example, a left side, while overlapping the boundary portion between the first portion 151 and the second portion 152.

Likewise, the third active hole AH3 and the fourth active hole AH4 may overlap the first portion 151 and the third portion 153 of the gate electrode 150. For example, the third active hole AH3 and the fourth active hole AH4 may overlap a boundary portion between the first portion 151 and the third portion 153, and further, the third active hole AH3 may overlap one side of the first portion 151, for example, a right side while overlapping a boundary portion between the first portion 151 and the third portion 153, and the fourth active hole AH4 may overlap another side of the first portion 151, for example, a left side while overlapping the boundary portion between the first portion 151 and the third portion 153.

According to an embodiment of the present disclosure, because the gate electrode 150 includes the first portion 151, the second portion 152, and the third portion 153, the channel part formed in the active layer 130 through the conducting process may also be formed in the same or substantially same shape as the gate electrode 150 according to an embodiment of the present disclosure.

In this case, because the channel part includes a dualized channel part having different lengths, the thin film transistor substrate according to an embodiment of the present disclosure may simultaneously secure improved on-current characteristics and S-factor characteristics. Furthermore, because the gate electrode 150 includes the first portion 151, the second portion 152, and the third portion 153, only the first portion 151 and the second portion 152 may overlap the active layer 130 by an error in a process, and a dualized channel part may be formed even when the third portion 153 does not overlap the active layer 130. In this case, improved on-current characteristics and S-factor characteristics may be obtained in the same or substantially same manner as the thin film transistor substrate described above with reference to FIG. 1A.

FIG. 10B is a cross-sectional view of a thin film transistor substrate according to another embodiment of the present disclosure. In this case, the cross-sectional view of FIG. 10B corresponds to the cross-section taken along the line VI-VI′ of FIG. 10A. Meanwhile, although the cross-sections passing through the first active hole AH1 and the second active hole AH2 according to the embodiment of FIG. 10A are not shown in FIG. 10B, the cross-sections passing through the first active hole AH1 and the second active hole AH2 are the same as or substantially the same as those of the embodiment of FIG. 2A, and thus, only the cross-sections passing through the third active hole AH3 and the fourth active hole AH4 according to the embodiment of FIG. 10A will be described below. Furthermore, because the thin film transistor substrate according to FIG. 10B is the same as or substantially the same as the thin film transistor substrate according to FIG. 2A except for the configurations of the third active hole AH3 and the fourth active hole AH4, different configurations will be mainly described below.

As shown in FIG. 10B, the active layer 130 may include a channel part 131, a first connection part 133a connected to one side of the channel part 131, for example, a right side, and a second connection part 133b connected to another side of the channel part 131, for example, a left side of the channel part 131, a third active hole AH3 may be provided between the channel part 131 and the first connection part 133a, and a fourth active hole AH4 may be provided between the channel part 131 and the second connection part 133b.

The channel part 131 may include a first region 131a, a second region 131b provided on one side of the first region 131a, and a third region 131c provided on another side of the first region 131a. The first region 131a may be spaced apart from the second region 131b and the third region 131c by the third active hole AH3 and the fourth active hole AH4.

The gate electrode 150 may include a first portion 151 having a first length W1 in the first direction and a third portion 153 having a third length W3 in the first direction. The first portion 151 may overlap the first region 131a of the channel part 131, but may not overlap the second region 131b and the third region 131c of the channel part 131. Meanwhile, the third portion 153 may not overlap the first region 131a of the channel part 131, but may overlap the second region 131b and the third region 131c of the channel part 131. The first portion 151 and the third portion 153 may overlap the third active hole AH3 and the fourth active hole AH4, respectively.

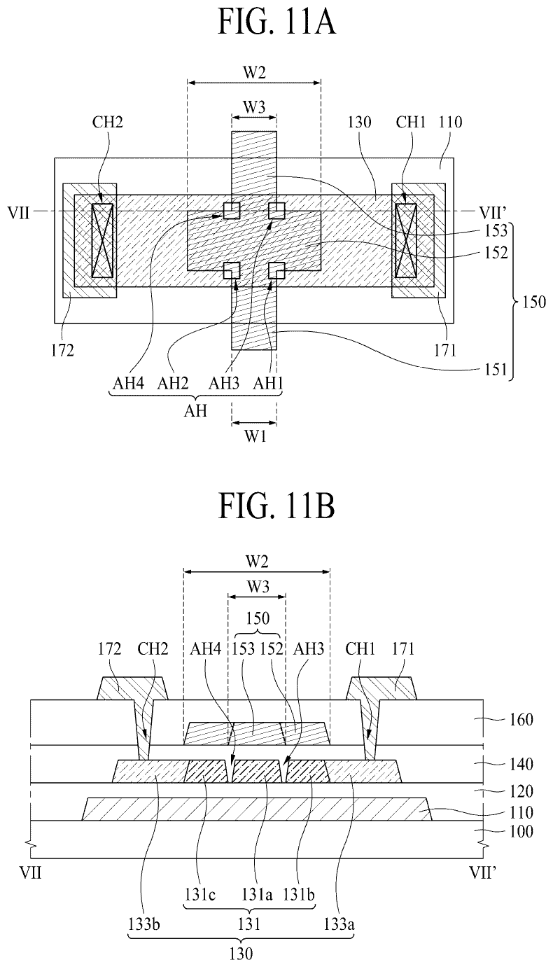

FIG. 11A is a plan view of a thin film transistor substrate according to another embodiment of the present disclosure. Meanwhile, the thin film transistor substrate according to FIG. 11A is the same as or substantially the same as the thin film transistor substrate according to FIG. 10A except that the first portion, the second portion, and the third portion of the gate electrode have different lengths, and thus different configurations will be mainly described below.

As shown in FIG. 11A, the gate electrode 150 may include a first portion 151 having a first length W1, a second portion 152 having a second length W2, and a third portion 153 having a third length W3. In this case, the first length W1 of the first portion 151 and the third length W3 of the third portion 153 may be shorter than the second length W2 of the second portion 152.

According to an embodiment of the present disclosure, the first portion 151 and the third portion 153 may be provided symmetrically with respect to the second portion 152. Thus, the first length W1 of the first portion 151 may be the same as or substantially the same as the third length W3 of the third portion 153. However, the present disclosure is not limited thereto, and the first length W1 and the third length W3 may be different from each other.

According to an embodiment of the present disclosure, the first active hole AH1 may overlap one side of the first portion 151, for example, a right side while overlapping a boundary portion between the first portion 151 and the second portion 152. and the second active hole AH2 may overlap another side of the first portion 151, for example, a left side, while overlapping the boundary portion between the first portion 151 and the second portion 152.

Likewise, the third active hole AH3 may overlap one side of the third portion 153, for example, a right side while overlapping a boundary portion between the second portion 152 and the third portion 153. and the fourth active hole AH4 may overlap another side of the third portion 153, for example, a left side while overlapping the boundary portion between the second portion 152 and the third portion 153.

According to an embodiment of the present disclosure, because the gate electrode 150 includes the first portion 151, the second portion 152, and the third portion 153, the channel part formed in the active layer 130 through the conducting process may also be formed in the same or substantially same shape as the gate electrode 150 according to an embodiment of the present disclosure.

In this case, because the channel part includes a dualized channel part having different lengths, the thin film transistor substrate according to an embodiment of the present disclosure may simultaneously secure improved on-current characteristics and S-factor characteristics.

Furthermore, because the gate electrode 150 includes the first portion 151, the second portion 152, and the third portion 153, only the first portion 151 and the second portion 152 may overlap the active layer 130 by an error in a process, and a dualized channel part may be formed even when the third portion 153 does not overlap the active layer 130. In this case, improved on-current characteristics and S-factor characteristics may be obtained in the same or substantially same manner as those of the thin film transistor substrate described above with reference to FIG. 1A.

FIG. 11B is a cross-sectional view of a thin film transistor substrate according to another embodiment of the present disclosure. In this case, the cross-sectional view of FIG. 11B corresponds to the cross-section taken along the line VII-VII′ of FIG. 11A. Meanwhile, although FIG. 11B does not illustrate cross-sections passing through the first active hole AH1 and the second active hole AH2 according to the embodiment of FIG. 11A, the cross-sections passing through the first active hole AH1 and the second active hole AH2 are the same as or substantially the same as those of the embodiment of FIG. 2A, and thus, only cross-sections passing through the third active hole AH3 and the fourth active hole AH4 according to the embodiment of FIG. 11A will be described below. Furthermore, the thin film transistor substrate of FIG. 11B is the same as or substantially the same as the thin film transistor substrate of FIG. 10B except for the configuration of the gate electrode 150, and thus different configurations will be mainly described below.

The gate electrode 150 may include a second portion 152 having a second length W2 in the first direction and a third portion 153 having a third length W3 in the first direction. The second portion 152 may not overlap the first region 131a of the channel part 131, but may overlap the second region 131b and the third region 131c of the channel part 131.

Meanwhile, the third portion 153 may overlap the first region 131a of the channel part 131, but may not overlap the second region 131b and the third region 131c of the channel part 131. The second portion 152 and the third portion 153 may overlap the third active hole AH3 and the fourth active hole AH4, respectively.

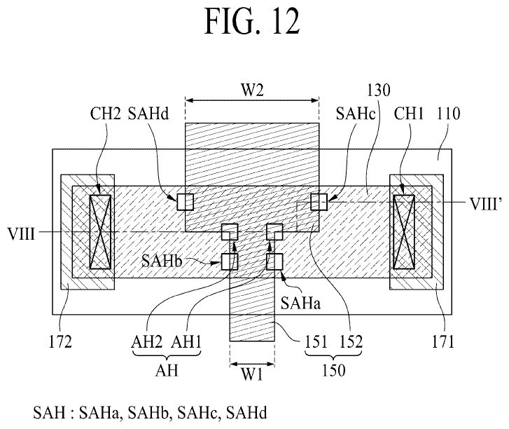

FIG. 12 is a plan view of a thin film transistor substrate according to another embodiment of the present disclosure. Meanwhile, because the thin film transistor substrate according to FIG. 12 is the same as or substantially the same as the thin film transistor substrate according to FIG. 1A except that a sub-active hole is additionally provided in an active layer, different configurations will be mainly described below.

As shown in FIG. 12, a sub-active hole SAH overlapping the gate electrode 150 may be additionally provided in the active layer 130. In this case, the sub-active hole SAH may include a first sub-active hole SAHa, a second sub-active hole SAHb, a third sub-active hole SAHc, and a fourth sub-active hole SAHd.

The first sub-active hole SAHa and the second sub-active hole SAHb may overlap the first portion 151 of the gate electrode 150, and the third sub-active hole SAHc and the fourth sub-active hole SAHd may overlap the second portion 152 of the gate electrode 150. For example, the first sub-active hole SAHa overlaps one side of the first portion 151, for example, the right side, the second sub-active hole SAHb overlaps another side of the first portion 151, for example, the left side, the third sub-active hole SAHc overlaps one side of the second portion 152, for example, the right side, and the fourth sub-active hole SAHd may overlap another side of the second portion 152, for example, the left side.

According to an embodiment of the present disclosure, by providing a sub-active hole SAH overlapping the gate electrode 150, when the conducting process is performed in a partial area of the active layer 130 with the gate electrode 150 as a mask, dopant ions or plasma more than those designed in the area where the channel part of the active layer 130 is formed may not be diffused, so that the same or substantially same channel part having the same or substantially same length as designed may be secured.

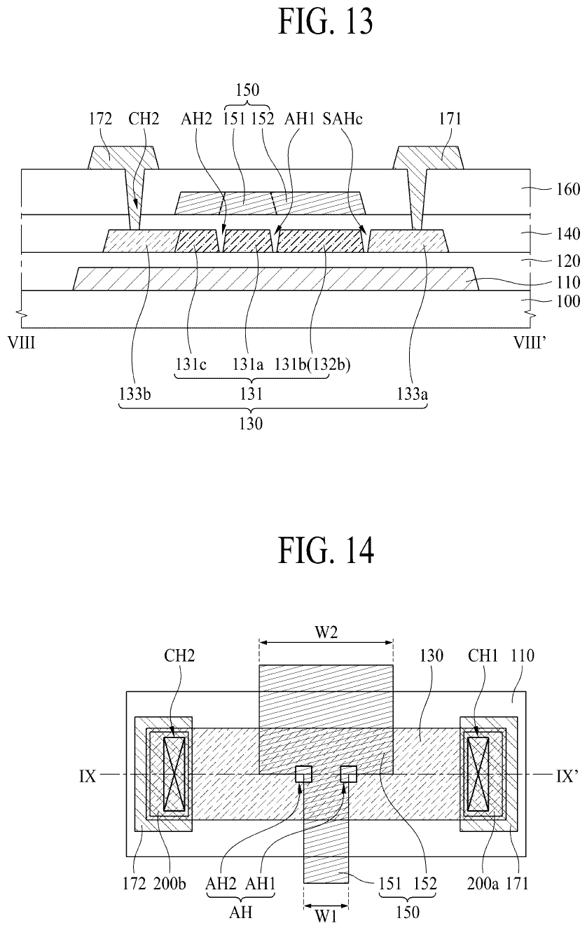

FIG. 13 is a cross-sectional view of a thin film transistor substrate according to another embodiment of the present disclosure. In this case, the cross-sectional view of FIG. 13 corresponds to the cross-section taken along the line VIII-VIII′ of FIG. 12. Meanwhile, the thin film transistor substrate of FIG. 13 is the same as or substantially the same as the thin film transistor substrate of FIG. 2A except that a sub-active hole is additionally provided in an active layer, and thus different configurations will be mainly described below.

As shown in FIG. 13, the active layer 130 may include a channel part 131, a first connection part 133a provided on one side of the channel part 131, for example, on the right side, and a second connection part 133b provided on another side of the channel part 131, for example, on the left side.

The channel part 131 may include a first region 131a overlapping the first portion 151 of the gate electrode 150, a second region 131b and a third region 131c overlapping the second portion 152 of the gate electrode 150. Meanwhile, the second region 131b may correspond to the second channel part 132b of FIG. 2A.

The third sub-active hole SAHc may be provided at one end of the channel part 131, for example, a right end, and may be provided between the channel part 131 and the first connection part 133a. Although not shown in detail, a first sub-active hole (see SAHa of FIG. 12) may also be provided between the channel part 131 and the first connection part 133a. Likewise, the second sub-active hole SAHb and the fourth sub-active hole SAHd may be provided between the channel part 131 and the second connection part 133b.

According to an embodiment of the present disclosure, the third sub-active hole SAHc may overlap one end of the second portion 152 of the gate electrode 150, for example, a right end. By forming in this way, when some regions of the active layer 130 are conductive through the conducting process using the gate electrode 150 as a mask, dopant ions or plasma diffused into the first connection part 133a may not be introduced into the channel part 131 by the third sub-active hole SAHc. Accordingly, the thin film transistor substrate according to an embodiment of the present disclosure may secure a designed channel length.

FIG. 14 is a plan view of a thin film transistor substrate according to another embodiment of the present disclosure. Meanwhile, because the thin film transistor substrate of FIG. 14 is the same as or substantially the same as the thin film transistor substrate of FIG. 1A except for the configuration of the conductive material layer, different configurations will be mainly described below.

As shown in FIG. 14, the thin film transistor substrate according to an embodiment of the present disclosure may further include a first conductive material layer 200a provided on one side of the active layer 130, for example, on the right side, and a second conductive material layer 200b provided on another side, for example, on the left side, of the active layer 130.

The first conductive material layer 200a may be electrically connected to one side of the active layer 130, and may be electrically connected to the source electrode 171 through the first contact hole CH1. Likewise, the second conductive material layer 200b may be electrically connected to another side of the active layer 130, and may be electrically connected to the drain electrode 172 through the second contact hole CH2.

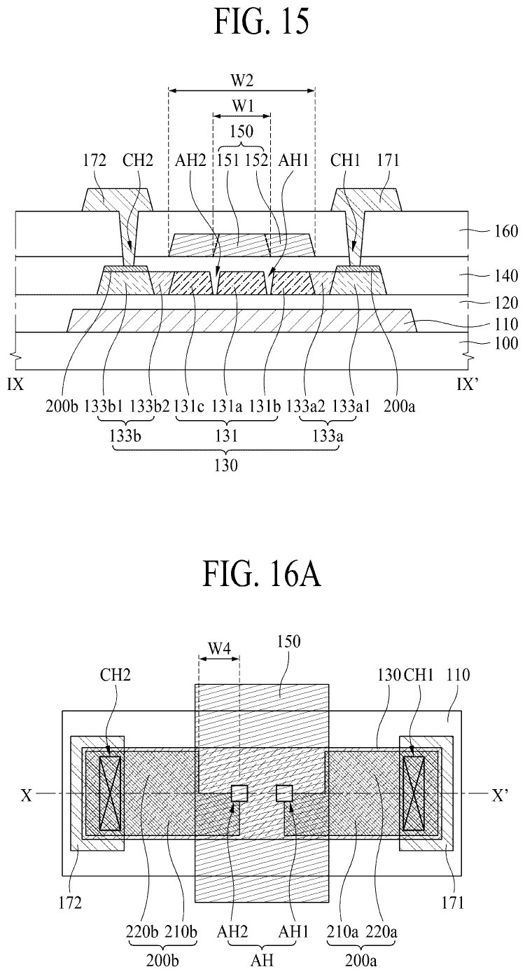

FIG. 15 is a cross-sectional view of a thin film transistor substrate according to another embodiment of the present disclosure. In this case, the cross-sectional view of FIG. 15 corresponds to the cross-section taken along the line of IX-IX′ of FIG. 14. Meanwhile, the thin film transistor substrate of FIG. 15 is the same as or substantially the same as the thin film transistor substrate of FIG. 2A except for configurations of the conductive material layer, the first connection part, and the second connection part, and thus different configurations will be mainly described below.

As shown in FIG. 15, the thin film transistor substrate according to an embodiment of the present disclosure may further include a first conductive material layer 200a and a second conductive material layer 200b provided on the active layer 130.

According to an embodiment of the present disclosure, the active layer 130 may include a channel part 131, a first connection part 133a provided on one side of the channel part 131, for example, on the right side, and a second connection part 133b provided on another side, for example, on the left side of the channel part 131. The first connection part 133a may include a first non-conductive connection part 133al and a first conductive connection part 133a2, and the second connection part 133b may include a second non-conductive connection part 133b1 and a second conductive connection part 133b2.

The first conductive connection part 133a2 and the second conductive connection part 133b2 may be connected to one side of the channel part 131, for example, the right side and another side, for example, the left side, and may have conductive characteristics in a conducting process in which the gate electrode 150 and the conductive material layers 200a and 200b are used as masks.

The first non-conductive connection part 133al may be provided on one side of the first conductive connection part 133a2, for example, on the right side, and the second non-conductive connection part 133b1 may be provided on another side, for example, on the left side, of the second conductive connection part 133b2. Meanwhile, the first non-conductive connection part 133al and the second non-conductive connection part 133b1 may be regions in which a separate conducting process is not performed.

The first conductive material layer 200a may be provided on the upper surface of the first connection part 133a, and the second conductive material layer 200b may be provided on the upper surface of the second connection part 133b. For example, the first conductive material layer 200a may be in contact with the upper surface of the first non-conductive connection part 133al, and the second conductive material layer 200b may be in contact with the upper surface of the second non-conductive connection part 133b1.

The first conductive material layer 200a may be provided on the first connection part 133a, and may be electrically connected to the source electrode 171 through the first contact hole CH1. Furthermore, the second conductive material layer 200b may be provided on the second connection part 133b, and may be electrically connected to the drain electrode 172 through the second contact hole CH2.

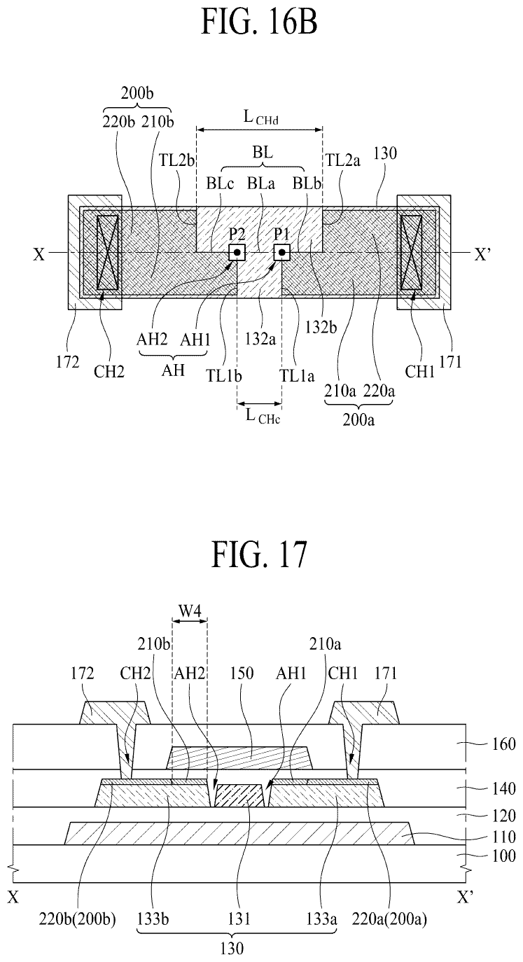

FIG. 16A is a plan view of a thin film transistor substrate according to another embodiment of the present disclosure. Meanwhile, the thin film transistor substrate according to FIG. 16A is the same as or substantially the same as the thin film transistor substrate of FIG. 1A except for configurations of a gate electrode and a conductive material layer, and thus different configurations will be mainly described below.

As shown in FIG. 16A, the thin film transistor substrate according to another embodiment of the present disclosure may include a light blocking layer 110, an active layer 130, a gate electrode 150, a source electrode 171, a drain electrode 172, and conductive material layers 200a and 200b.

According to another embodiment of the present disclosure, the gate electrode 150 may extend in a second direction, for example, a vertical direction, and may have the same or substantially same length in a first direction, for example, a horizontal direction. Accordingly, unlike the gate electrode of the thin film transistor substrate of FIG. 1A, the gate electrode may not have a boundary portion according to different lengths.

According to another embodiment of present disclosure, the first conductive material layer 200a may be provided on one side of the active layer 130, and include a fourth portion 210a and a fifth portion 220a with different lengths, and the second conductive material layer 200b may be provided on another side of the active layer 130, and include a sixth portion 210b and a seventh portion 220b with different lengths.

One side of the fourth portion 210a, for example, a left side, may be spaced apart from one side of the fifth portion 220a, for example, a left side by a fourth length W4 in the first direction, for example, a left side. and one side of the sixth portion 210b, for example, a right side may be spaced apart from one side of the seventh portion 220b, for example, a right side by a fourth length W4 in the first direction. In other words, the fourth portion 210a may be provided from the center of the active layer 130 by the fourth length W4 than the fifth portion 220a, and the sixth portion 210b may be provided from the center of the active layer 130 by the fourth length W4 than the seventh portion 220b.

Because the first conductive material layer 200a and the second conductive material layer 200b may be divided into regions having different lengths, the channel part provided in the active layer 130 may be dualized into different lengths, which will be described in detail with reference to FIG. 16B.

FIG. 16B is a schematic plan view illustrating a state in which a channel of a thin film transistor substrate is formed. In this case, FIG. 16B illustrates a channel of the thin film transistor substrate of FIG. 16A. Meanwhile, FIG. 16B is the same as or substantially the same as FIG. 1B except for the configurations of the first conductive material layer and the second conductive material layer, and thus different configurations will be mainly described below.

As shown in FIG. 16B, the active layer 130 may include channel parts 132a and 132b dualized by the structures of the first conductive material layer 200a and the second conductive material layer 200b. The channel part 132 may include a first channel part 132a having a third channel length LCHc in the first direction and a second channel part 132b having a fourth channel length LCHd in the first direction. In this case, the first channel part 132a and the second channel part 132b are continuously formed.

According to another embodiment of the present disclosure, the first channel part 132a and the second channel part 132b may be dualized by conductive material layers 200a and 200b, not gate electrodes, unlike of FIG. 1B. For example, the first channel part 132a may be provided between the fourth portion 210a of the first conductive material layer 200a and the sixth portion 210b of the second conductive material layer 200b, and the second channel part 132b may be provided between the fifth portion 220a of the first conductive material layer 200a and the seventh portion 220b of the second conductive material layer 200b.

In this case, because the fourth portion 210a and the fifth portion 220a are different from each other by the fourth length W4, and the sixth portion 210b and the seventh portion 220b are different from each other by the fourth length W4, the fourth portion 210a may be provided to be closer to a center of the channel parts 132a and 132b by the fourth length W4 than the fifth portion 220a, and the sixth portion 210b may be provided to be closer to the center of the channel parts 132a and 132b by the fourth length W4 than the seventh portion 220b.

Accordingly, the third channel length LCHc of the first channel part 132a provided between the fourth portion 210a and the sixth portion 210b may be shorter than the fourth channel length LCHd of the second channel part 132b provided between the fifth portion 220a and the seventh portion 220b.

According to an embodiment of the present disclosure, because the active layer 130 includes the first channel part 132a and the second channel part 132b having different lengths, when the thin film transistor according to an embodiment of the present disclosure is turned on, high on-current characteristics may be secured because current flows through the first channel part 132a having a relatively short length, and high S-factor characteristics may be secured because current flows through the second channel part 132b having a relatively long length. Accordingly, the thin film transistor substrate according to an embodiment of the present disclosure may simultaneously secure high on-current characteristics and high S-factor characteristics.

The active hole AH may be provided at the boundary portion BL provided between the first channel part 132a and the second channel part 132b. For example, the first active hole AH1 may be provided between the first boundary portion BLa and the second boundary portion BLb, and the second active hole AH2 may be provided between the first boundary portion BLa and the third boundary portion BLc.

The first active hole AH1 may overlap an extension line of the first side TL1a of the first channel part 132a, and the second active hole AH2 may overlap an extension line of the second side TL1b of the first channel part 132a. The first active hole AH1 and the second active hole AH2 may be formed to be spaced apart from each other. Therefore, the first active hole AH1 and the second active hole AH2 are not continuously formed.

According to an embodiment of the present disclosure, when the first active hole AH1 and the second active hole AH2 are formed in the boundary portion BL between the first channel part 132a and the second channel part 132b, current may not flow from the first channel part 132a to the second channel part 132b or from the second channel part 132b to the first channel part 132a.

FIG. 17 is a cross-sectional view of a thin film transistor substrate according to another embodiment of the present disclosure. In this case, the cross-sectional view of FIG. 17 corresponds to the cross-section taken along the line of X-X′ of FIG. 16A. Meanwhile, the thin film transistor of FIG. 17 is the same as or substantially the same as the thin film transistor of FIG. 2A except for configurations of an active layer, a gate electrode, and a conductive material layer, and thus different configurations will be mainly described below.

As shown in FIG. 17, the active layer 130 may include a channel part 131, a first connection part 133a provided on one side of the channel part 131, for example, on the right side, and a second connection part 133b provided on another side, for example, on the left side of the channel part 131, a separate conducting process may not be performed on the first connection part 133a and the second connection part 133b.

The conductive material layers 200a and 200b may be provided on the active layer 130. For example, the first conductive material layer 200a may be provided on the upper surface of the first connection part 133a, may be in contact with the first connection part 133a, and the second conductive material layer 200b may be provided on the upper surface of the second connection part 133b and may be in contact with the second connection part 133b. The first conductive material layer 200a may not overlap the first active hole AH1, and the second conductive material layer 200b may not overlap the second active hole AH2. The gate electrode 150 may be provided on the active layer 130, overlap the fourth portion 210a and the fifth portion 220a of the first conductive material layer 200a, and overlap the sixth portion 210b and the seventh portion 220b of the second conductive material layer 200b.

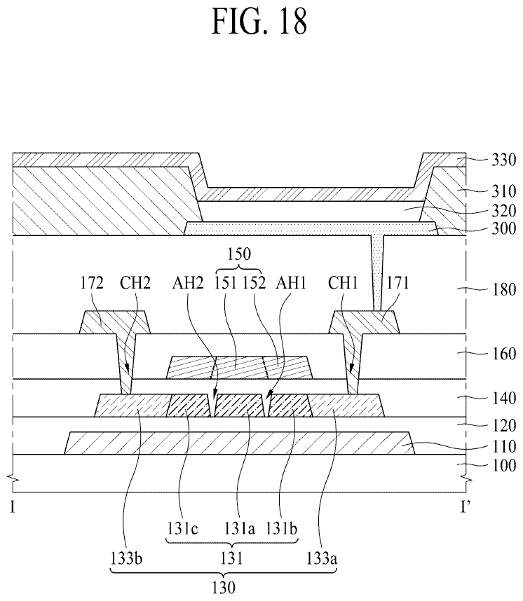

FIG. 18 is a cross-sectional view of a display apparatus including a thin film transistor substrate according to an embodiment of the present disclosure.

As shown in FIG. 18, the display apparatus according to an embodiment of the present disclosure may include a substrate 100, a light blocking layer 110, a buffer layer 120, an active layer 130, a gate insulating layer 140, a gate electrode 150, an interlayer insulating layer 160, a source electrode 171, a drain electrode 172, a planarization layer 180, a first electrode 300, a bank layer 310, a light emitting layer 320, and a second electrode 330.

The substrate 100, the light blocking layer 110, the buffer layer 120, the active layer 130, the gate insulating layer 140, the gate electrode 150, the interlayer insulating layer 160, the source electrode 171, and the drain electrode 172 are the same as or substantially the same as those described above, repeated descriptions thereof will be omitted or may be briefly provided.

A planarization layer 180 may be provided on the source electrode 171 and the drain electrode 172. A contact hole may be provided in the planarization layer 180 so that the source electrode 171 may be exposed by the contact hole. However, in some cases, the drain electrode 172 may be exposed by the contact hole.

The first electrode 300 may be formed on the planarization layer 180 and may be connected to the source electrode 171 or the drain electrode 172 through the contact hole. The first electrode 300 may function as an anode.

The bank layer 310 may be provided to cover an edge of the first electrode 300 to define a light emitting area. Accordingly, an upper surface area of the first electrode 300 exposed without being covered by the bank layer 310 becomes a light emitting area.

The light emitting layer 320 may be provided on the first electrode 300. The light emitting layer 320 may include red, green, and blue light emitting layers patterned for each pixel, or may be formed of a white light emitting layer connected from all pixels. When the light emitting layer 320 is formed of a white emission layer, the light emitting layer 320 may include, for example, a first stack including a blue emission layer, a second stack including a yellow green emission layer, and a charge generation layer provided between the first stack and the second stack, but is not limited thereto.

The second electrode 330 may be provided on the light emitting layer 320. The second electrode 330 may function as a cathode.

Although not shown, an encapsulation layer for preventing or at least reducing moisture or oxygen from penetrating may be additionally formed on the second electrode 330.

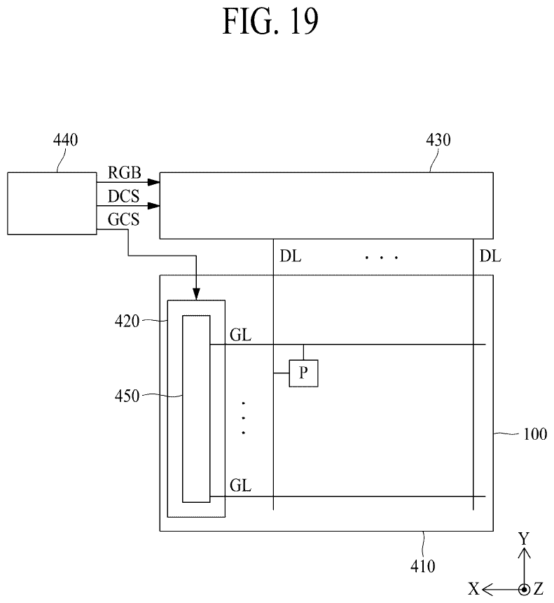

FIG. 19 is a schematic diagram of a display apparatus according to an embodiment of the present disclosure.

As shown in FIG. 19, the display apparatus according to an embodiment of the present disclosure may include a display panel 410, a gate driver 420, a data driver 430, and a controller 440. The display panel 410 includes gate lines GLs and data lines DLs, and pixels P are disposed in respective crossing areas of the gate lines GLs and data lines DLs. An image is displayed by driving the pixel P. The gate lines GLs, the data lines DLs, and the pixels P may be disposed on the substrate 100.

The controller 440 controls the gate driver 420 and the data driver 430. The controller 440 outputs a gate control signal GCS for controlling the gate driver 420 and a data control signal DCS for controlling the data driver 430 by using a signal supplied from an external system (not shown). Also, the controller 440 samples input video data input from the external system and rearranges the sampled input video data, and supplies the rearranged digital video data RGB to the data driver 430.

The gate control signal GCS includes a gate start pulse GSP, a gate shift clock GSC, a gate output enable signal GOE, a start signal Vst, and a gate clock GCLK. Further, control signals for controlling a shift register may be included in the gate control signal GCS.

The data control signal DCS includes a source start pulse SSP, a source shift clock signal SSC, a source output enable signal SOE, and a polarity control signal POL.

The data driver 430 supplies a data voltage to the data lines DL of the display panel 410. For example, the data driver 430 converts the video data RGB inputted from the controller 440 into an analog data voltage and supplies the data voltage to the data lines DL.

The gate driver 420 may be mounted on the display panel 410. As described above, a structure in which the gate driver 420 is directly mounted on the display panel 410 is referred to as a gate in panel (GIP) structure. For example, in the gate-in-panel (GIP) structure, the gate driver 420 may be disposed on the substrate 100. The gate driver 420 may include a shift register 350.

The shift register 350 sequentially supplies gate pulses to the gate lines GL during one frame by the use of start signal and gate clock transmitted from the controller 440. Herein, the one frame refers to a period in which one image is outputted through the display panel 410. The gate pulse has a turn-on voltage capable of turning on a switching device (thin film transistor) disposed in the pixel P.

Also, during the remaining period of one frame, in which the gate pulse is not supplied, the shift register 350 supplies a gate-off signal capable of turning off the switching device to the gate line GL. Hereinafter, the gate pulse and the gate-off signal are totally referred to as a gate signal GS.

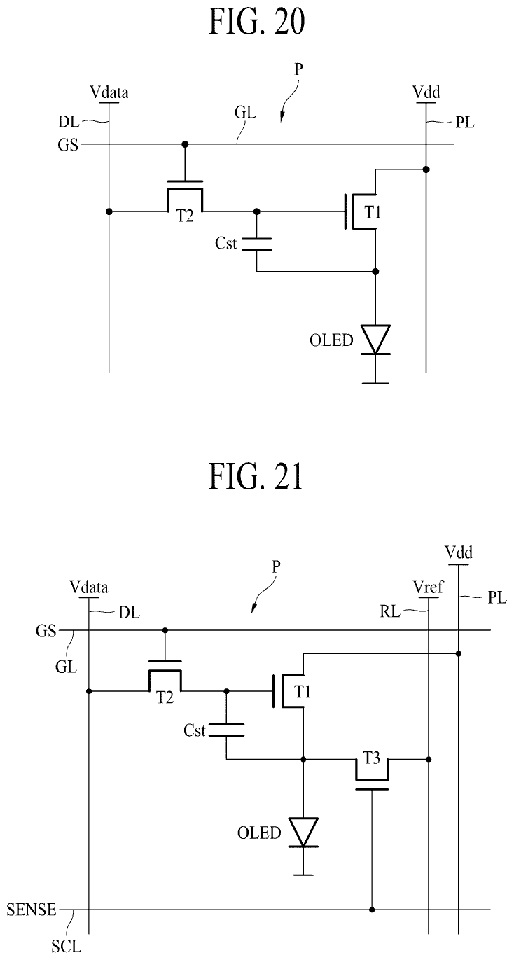

FIG. 20 is a circuit diagram of one pixel provided in a display apparatus according to an embodiment of the present disclosure.

As shown in FIG. 20, the display apparatus according to an embodiment of present disclosure includes first to second thin film transistors T1 and T2 and capacitors Cst. The first thin film transistor T1 is a driving thin film transistor, and the second thin film transistor T2 is a switching thin film transistor. At least one of the first thin film transistor T1 and the second thin film transistor T2 may be formed of the above-described various thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED. The second thin film transistor T2 is switched according to the gate signal GS supplied to the gate line GL and supplies the data voltage Vdata supplied from the data line DL to the first thin film transistor T1. The capacitor Cst serves to maintain the data voltage supplied to the first thin film transistor T1 for one frame, and is provided between the gate electrode and the source electrode of the first thin film transistor T1. The organic light emitting diode OLED emits predetermined light according to a data current supplied from the first thin film transistor T1.

FIG. 21 is a circuit diagram of one pixel provided in a display apparatus according to another embodiment of the present disclosure.

As shown in FIG. 21, the display apparatus according to another embodiment of present disclosure includes first to third thin film transistors T1, T2, T3 and a capacitor Cst. The first thin film transistor T1 is a driving thin film transistor, and the second to third thin film transistors T2 to T3 are switching thin film transistors. At least one of the first to third thin film transistors T1, T2, and T3 may be formed of the above-described various thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED. The second thin film transistor T2 is switched according to the gate signal GS supplied to the gate line GL and supplies the data voltage Vdata supplied from the data line DL to the first thin film transistor T1.

The third thin film transistor T3 supplies the current of the first thin film transistor T1 to the reference line RL in response to the sensing control signal SENSE supplied from the scan line SCL. A reference voltage Vref is supplied to the reference line RL.

The capacitor Cst serves to maintain the data voltage supplied to the first thin film transistor T1 for one frame, and is provided between the gate electrode and the source electrode of the first thin film transistor T1. The organic light emitting diode OLED emits predetermined light according to a data current supplied from the first thin film transistor T1.

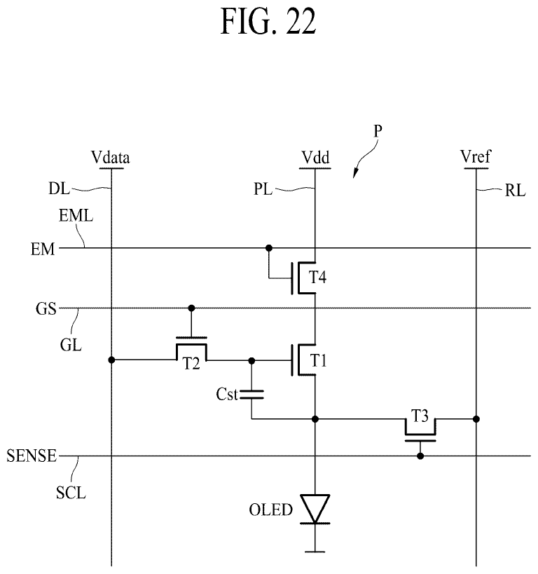

FIG. 22 is a circuit diagram of one pixel provided in a display apparatus according to another embodiment of the present disclosure.

As shown in FIG. 22, the display apparatus according to another embodiment of the present disclosure includes first to fourth thin film transistors T1, T2, T3, and T4 and a capacitor Cst.

The first thin film transistor T1 is a driving thin film transistor, and the second to fourth thin film transistors T2 to T4 are switching thin film transistors. At least one of the first to fourth thin film transistors T1, T2, T3, and T4 may be formed of the above-described various thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED. The second thin film transistor T2 is switched according to the gate signal GS supplied to the gate line GL and supplies the data voltage Vdata supplied from the data line DL to the first thin film transistor T1.

The third thin film transistor T3 supplies the current of the first thin film transistor T1 to the reference line RL in response to the sensing control signal SENSE supplied from the scan line SCL. A reference voltage Vref is supplied to the reference line RL.

The fourth thin film transistor T4 is switched according to the light emission control signal EM supplied to the light emission control line EML and supplies the driving voltage VDD supplied from the power line PL to the first thin film transistor T1.

The capacitor Cst serves to maintain the data voltage supplied to the first thin film transistor T1 for one frame, and is provided between the gate electrode and the source electrode of the first thin film transistor T1. The organic light emitting diode OLED emits predetermined light according to a data current supplied from the first thin film transistor T1.

Accordingly, the present disclosure may have the following example advantages.

According to an embodiment of present disclosure, because the active layer includes a first channel part and a second channel part having different lengths and continuously formed, on-current characteristics of the thin film transistor substrate may be improved and S-factor characteristics may also be improved.

According to an embodiment of the present disclosure, because an active hole is provided at a boundary portion provided between the first channel part and second channel part of the active layer, electrons may not move between the boundary portions provided between the first channel part and second channel part. Accordingly, the on-current characteristic and the S-factor improvement effect may not be deteriorated or lowered.

According to an embodiment of the present disclosure, the gate electrode includes a first portion, a second portion, and a third portion having different lengths, and thus the channel part of the active layer may be formed in the same or substantially same shape as the gate electrode. In this case, even if any one of the first to third portions does not overlap the active layer due to a process error, a dualized channel part of the active layer by the other two portions may be provided, and a thin film transistor substrate having improved on-current characteristics and S-factor characteristics may be implemented by the dualized channel part.

According to an embodiment of present disclosure, the active layer is provided with a sub-active hole, so that dopant ions or plasma used in the conducting process can be suppressed from spreading into the channel part of the active layer when conducting a process of conducting a partial area of the active layer with a gate electrode as a mask, thereby securing the same or substantially same length of the channel part as the design.

It will be apparent to those skilled in the art that various modifications and variations can be made in the thin film transistor substrate and the display device using the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A thin film transistor substrate, comprising:
a substrate;
an active layer on the substrate and including an active hole; and
a gate electrode on the active layer,
wherein the active layer includes a channel part including a first channel part having a first length and a second channel part continuous with the first channel part and having a second length, and
wherein the active hole includes a first active hole at a boundary portion between the first channel part and the second channel part.

2. The thin film transistor substrate according to claim 1, wherein the first active hole overlaps an extension line of one side of the first channel part.

3. The thin film transistor substrate according to claim 1, wherein the second length of the second channel part is longer than the first length of the first channel part.

4. The thin film transistor substrate according to claim 1, wherein a first width of the first channel part is greater than a second width of the second channel part.

5. The thin film transistor substrate according to claim 1, wherein the first active hole extends in a first direction and overlaps an extension line of one end of the second channel part.

6. The thin film transistor substrate according to claim 1, wherein the first active hole extends in a second direction and does not overlap an end of the active layer.

7. The thin film transistor substrate according to claim 1, wherein the active layer includes a first connection part on one side of the channel part, and
wherein the active layer further includes at least one of a first sub active hole between the first channel part and the first connection part, and a second sub active hole between the second channel part and the first connection part.

8. The thin film transistor substrate according to claim 1, wherein the active hole further includes a second active hole that is not continuous with the first active hole, and
wherein the second active hole is at a boundary portion between the first channel part and the second channel part and overlaps an extension line of another side of the first channel part.

9. The thin film transistor substrate according to claim 8, wherein the first active hole and the second active hole are symmetrical with respect to a center of the boundary portion.

10. The thin film transistor substrate according to claim 1, wherein the active layer further includes a third channel part continuous with the first channel part and having a third length,
wherein the third channel part is symmetric to the second channel part with respect to the first channel part,
wherein the third channel part further includes a third active hole in a boundary portion between the first channel part and the third channel part, and
wherein the third active hole overlaps an extension line of one end of the first channel part.

11. The thin film transistor substrate according to claim 10, wherein the first length of the first channel part is longer than the second length of the second channel part and the third length of the third channel part.

12. The thin film transistor substrate according to claim 1, wherein the active layer further includes a third channel part continuous with the second channel part and having a third length,
wherein the third channel part is symmetric to the second channel part with respect to the first channel part,
wherein the third channel part further includes a third active hole in a boundary portion between the first channel part and the third channel part, and
wherein the third active hole overlaps an extension line of one end of the third channel part.

13. The thin film transistor substrate according to claim 12, wherein the second length of the second channel part and the third length of the third channel part are longer than the first length of the first channel part.

14. The thin film transistor substrate according to claim 1, wherein the gate electrode includes a first portion overlapping the first channel part and having a third length, and a second portion continuous with the first portion, overlapping the second channel part and having a fourth length, and
wherein the active hole overlaps a boundary portion between the first portion and the second portion.

15. The thin film transistor substrate according to claim 1, wherein the active layer further includes a first connection part on one side of the channel part, and a first conductive material layer on the first connection part, and
wherein the first conductive material layer includes a third portion on an upper surface of the first connection part and a fourth portion on the upper surface of the first connection part and not overlapping the second channel part.

16. The thin film transistor substrate according to claim 15, wherein one end of the third portion corresponds to one end of the first channel part,
wherein one end of the fourth portion corresponds to one end of the second channel part, and
wherein the active hole does not overlap the conductive material layer.

17. A thin film transistor substrate, comprising:
a substrate;
an active layer on the substrate; and
a gate electrode on the active layer,
wherein the active layer includes a first channel part overlapping the gate electrode and having a first length, and a second channel part continuous with the first channel part, overlapping the gate electrode, and having a second length, and
wherein the active layer includes an active hole so that carrier does not move from the second channel part to the first channel part.

18. The thin film transistor substrate according to claim 17, wherein a length of the moving path bypassing the active hole from one end of the second channel part to the first channel part is longer than a length of the moving path from one end of the second channel part to another end of the second channel part, so that the carrier does not move from the second channel part to the first channel part.

19. The thin film transistor substrate according to claim 17, wherein the active hole includes a first active hole adjacent to one end of the first channel part and a second active hole adjacent to another end of the first channel part, and
wherein a distance t between the first active hole and the second active hole satisfy Equation 1 below:
$$0 < t < ( {d}^{2} - {L}^{2} ) / ( 2 L ) \qquad [ Equation 1 ]$$
where L is a distance in a first direction from one end of the first channel part to an extension line of another end of the second channel part, and d is a distance in a second direction of the active hole.

20. A display device including the thin film transistor substrate, comprising:
a substrate;
an active layer on the substrate and including an active hole; and
a gate electrode on the active layer,
wherein the active layer includes a channel part including a first channel part having a first length and a second channel part continuous with the first channel part and having a second length, and
wherein the active hole includes a first active hole at a boundary portion between the first channel part and the second channel part.
